(19) United States
(12) Patent Application Publication
(10) Pub. No.: US 2025/0329573 A1
(43) Pub. Date: Oct. 23, 2025

(54) SEMICONDUCTOR DEVICE HAVING ISOLATION LINER AND METHOD OF MANUFACTURING THEREOF

(71) Applicant: Taiwan Semiconductor Manufacturing Co., Ltd., Hsinchu (TW)

(72) Inventors: Yu-Wei Chou, Hsinchu (TW); Yen-Chun Huang, Taipei City (TW); Zhen-Cheng Wu, Hsinchu (TW); Tze-Liang Lee, Hsinchu (TW)

(21) Appl. No.: 18/643,083

(22) Filed: Apr. 23, 2024

(51) Int. Cl. H01L 21/762; H01L 29/06; H01L 29/423; H01L 29/66; H01L 29/775

(52) U.S. Cl. CPC H01L 21/76224; H10D 30/014; H10D 30/43; H10D 30/6735; H10D 62/121; H10D 64/017

(57) ABSTRACT

In some embodiments, a semiconductor device is provided. The semiconductor device includes a channel over substrate; a gate over the channel and interposed between source/drain regions; an etch stop layer around sidewalls of the gate and over the substrate and source/drain regions; and an interlayer dielectric over the etch stop layer. The interlayer dielectric includes a liner and a main dielectric over the liner. The liner and the main dielectric both include at least silicon, oxygen, and carbon. The main dielectric includes a lower portion and an upper portion, and a first carbon concentration of the main dielectric at the lower portion is greater than a second carbon concentration of the main dielectric at the upper portion.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B 8A, 8B, 9A, 9B, 10A, 10B, 11A, 11B, 11C, 12A, 12B, 12C, 12D, 13A, 13B, 13C, 14A, 14B, 14C, 14D, 15A, 15B, 16A, 16B, 17A, 17B, 18A, 18B, 19A, 19B, 19C, 20A, 20B, 20C, 21A, 21B, and 21C are cross-sectional views of intermediate stages in the manufacturing of nano-FETs, in accordance with some embodiments.

FIGS. 22A, 22B, and 22C are cross-sectional views of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As discussed in greater detail below, embodiments of the present disclosure describe transistors having an interlayer dielectric around gate electrodes, wherein the interlayer dielectric has good film quality although the interlayer dielectric is cured by a low-temperature anneal process. The techniques described herein include forming a carbon-containing liner prior to forming a main dielectric of the interlayer dielectric layer so that carbon in the liner can be diffused to the main dielectric to improve film quality of the interlayer dielectric. Embodiments are described below in a particular context, a die comprising nano-FETs. Various embodiments may be applied, however, to dies comprising other types of transistors, such as FinFETs, planar transistors, or the like, in lieu of or in combination with the nano-FETs.

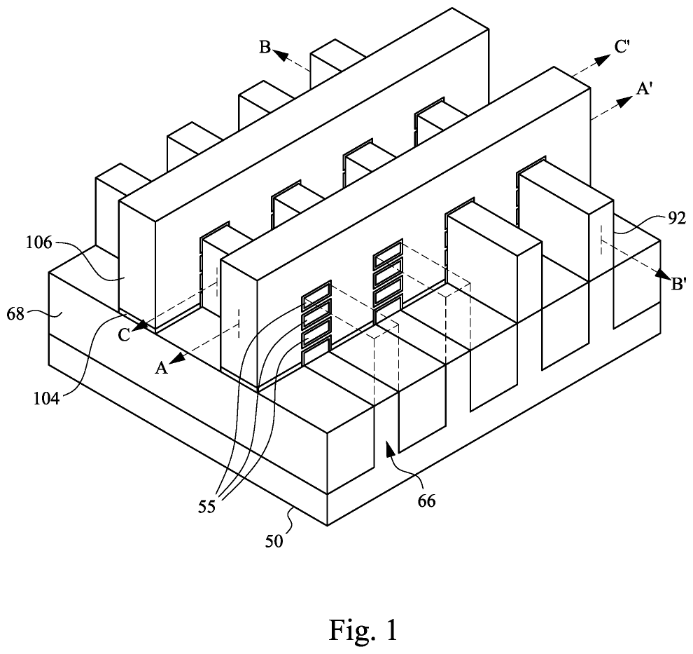

FIG. 1 illustrates an example of nano-FETs in a three-dimensional view, in accordance with some embodiments. The nano-FETs comprise nanostructures 55 (e.g., nanosheets or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 104 are over top surfaces of the fins 66 and along top surfaces, sidewalls, and bottom surfaces of the nanostructures 55. Gate electrodes 106 are over the gate dielectric layers 104. Epitaxial source/drain regions 92 are disposed on the fins 66 on opposing sides of the gate dielectric layers 104 and the gate electrodes 106.

FIG. 1 further illustrates reference cross-sections that are used in later figures. Cross-section A-A′ is along a longitudinal axis of a gate electrode 106 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

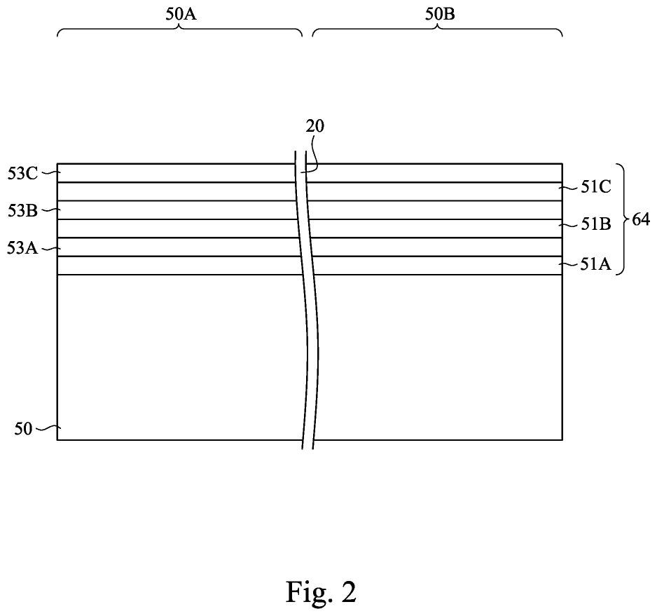

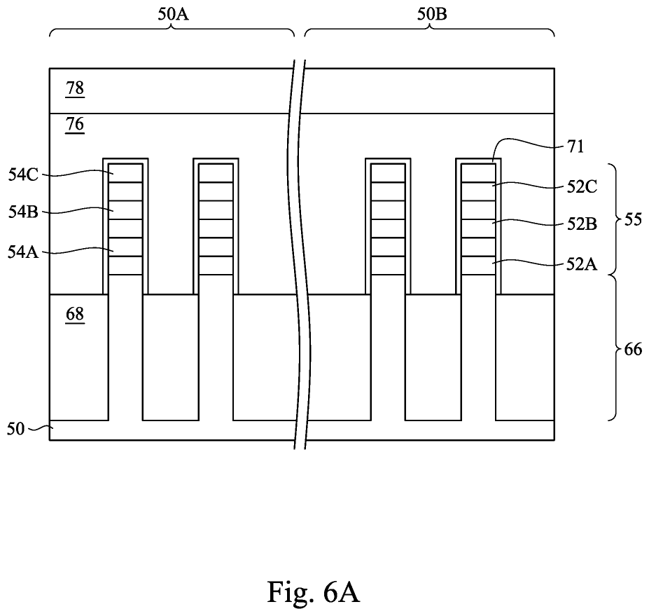

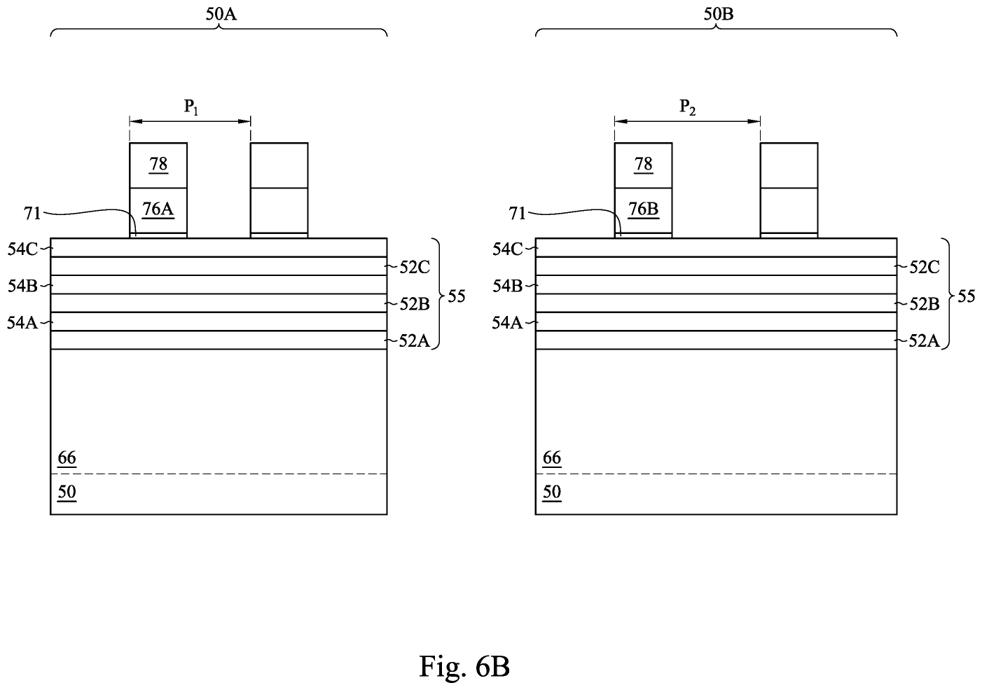

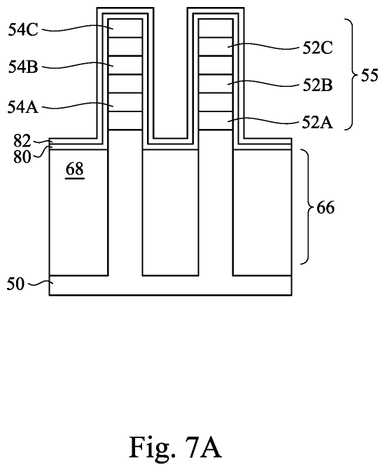

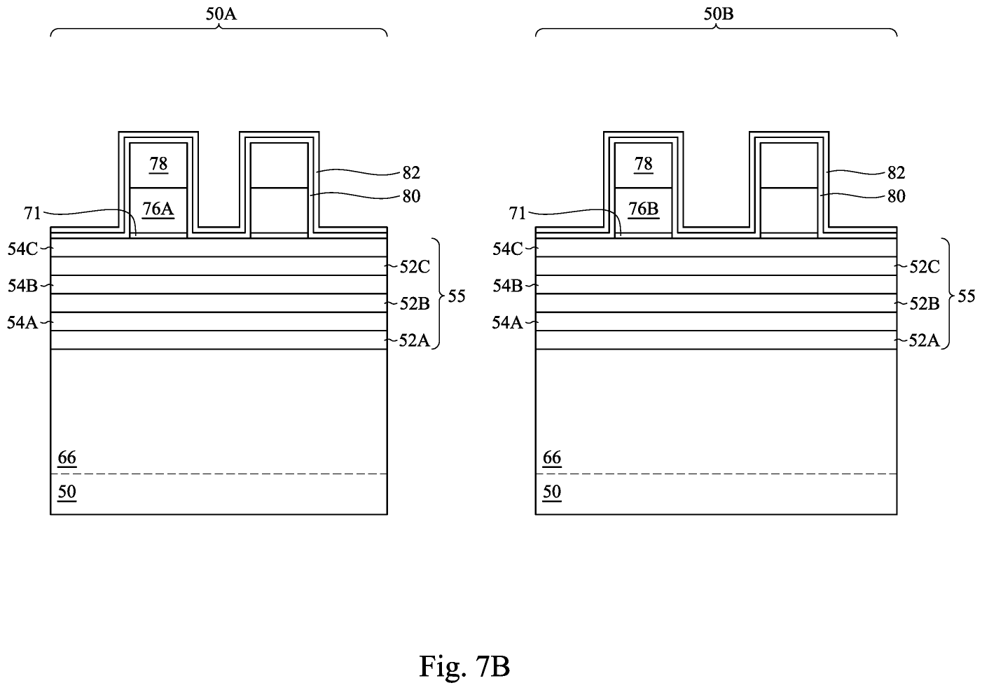

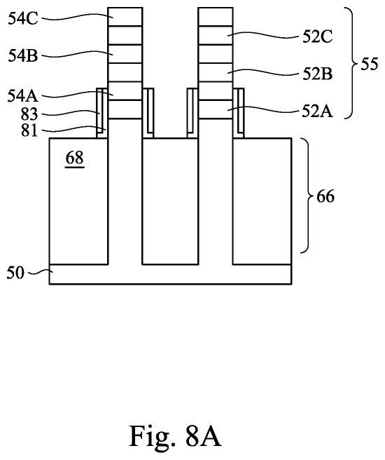

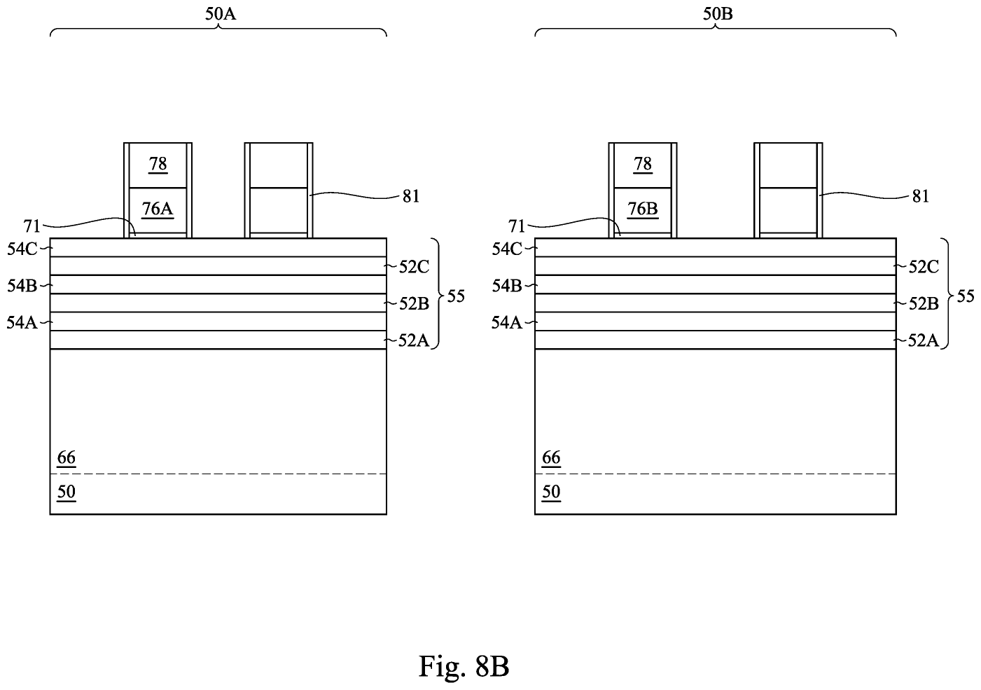

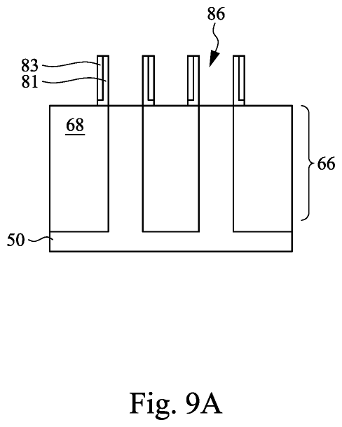

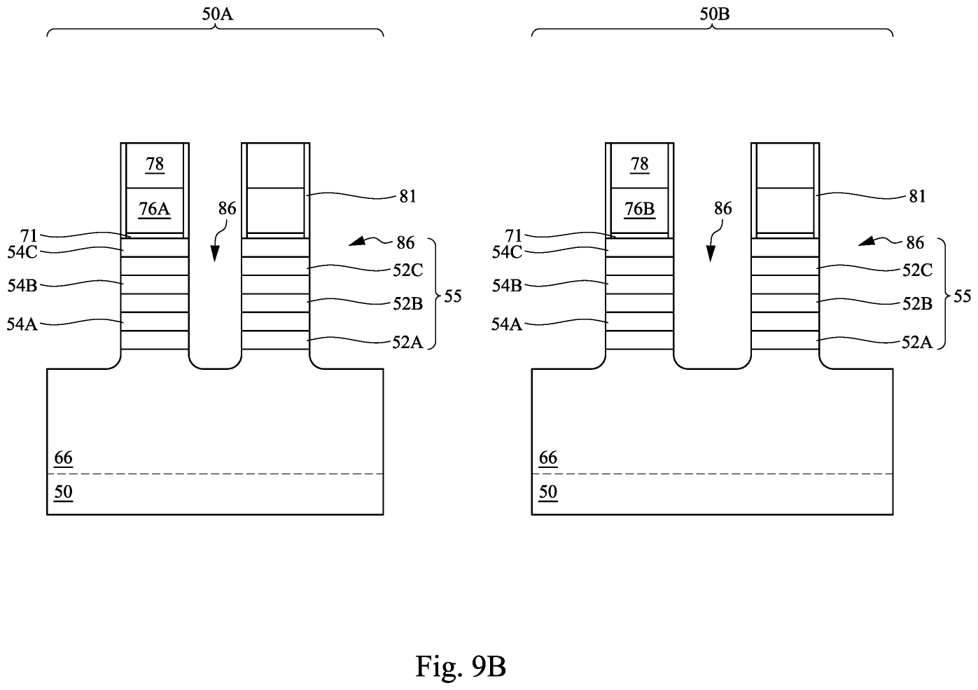

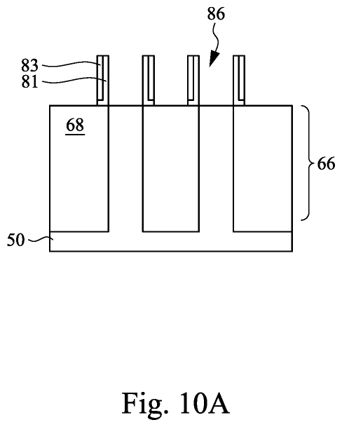

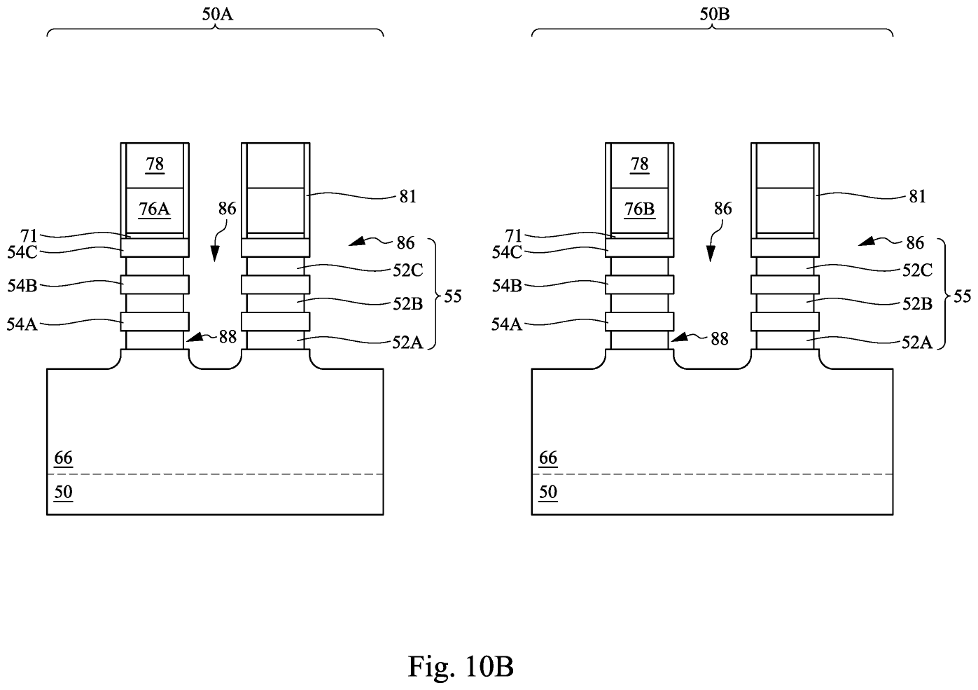

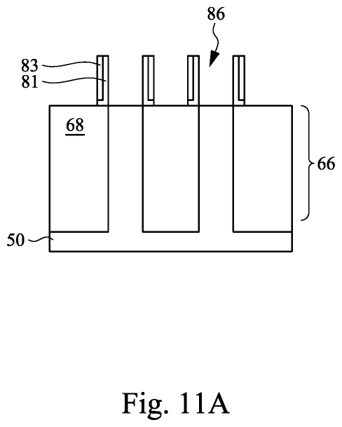

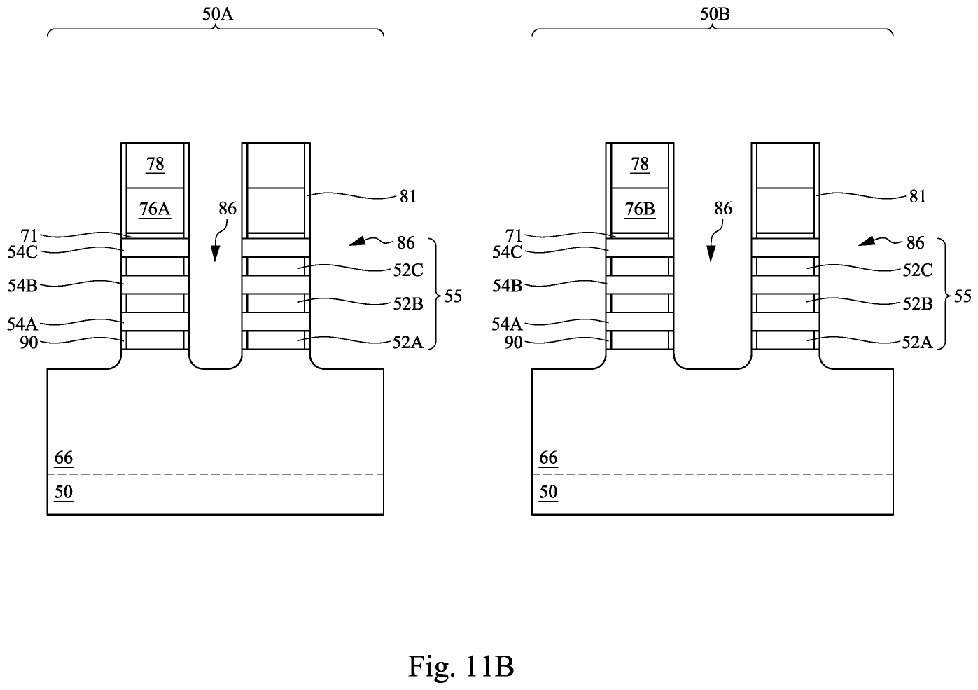

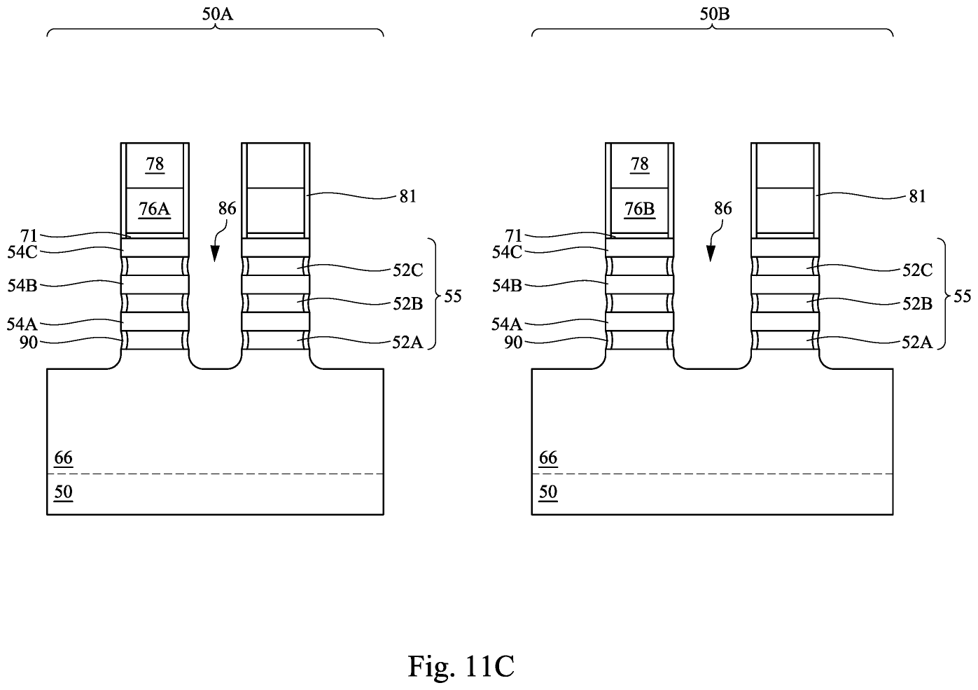

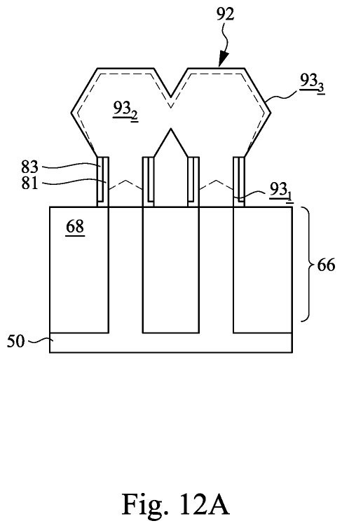

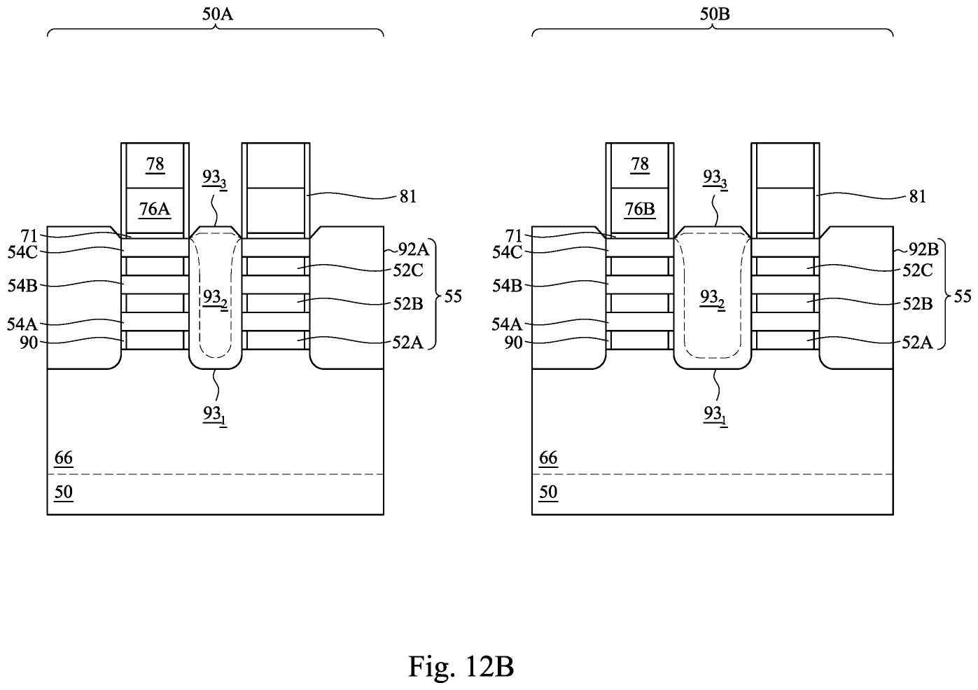

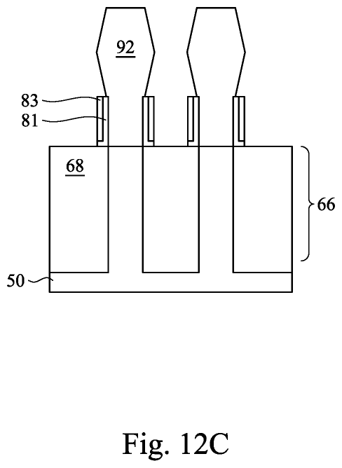

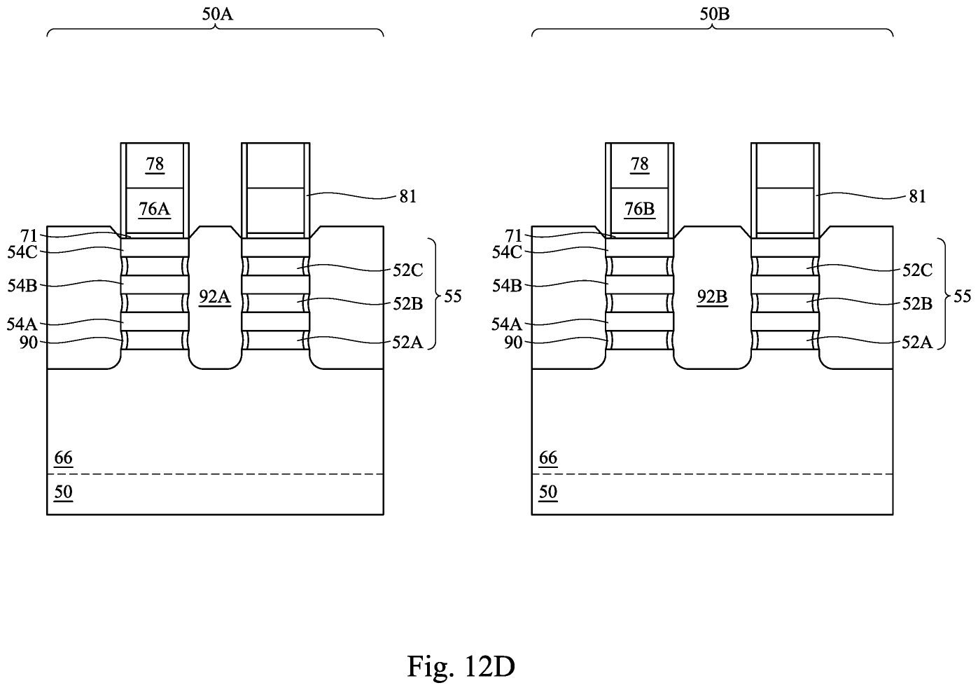

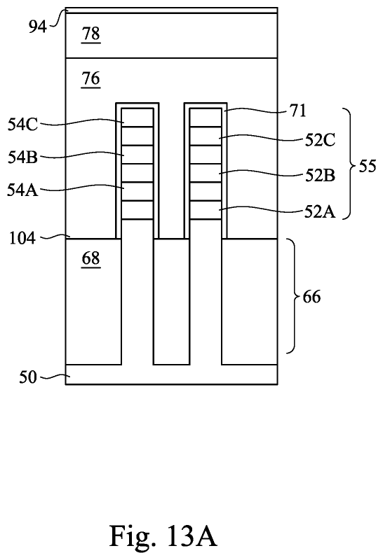

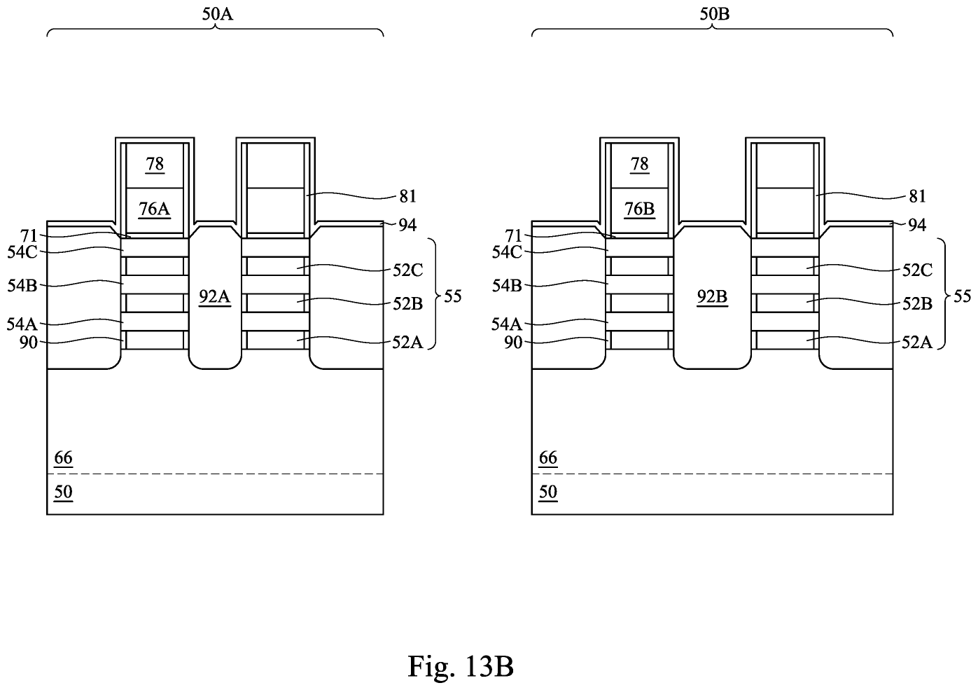

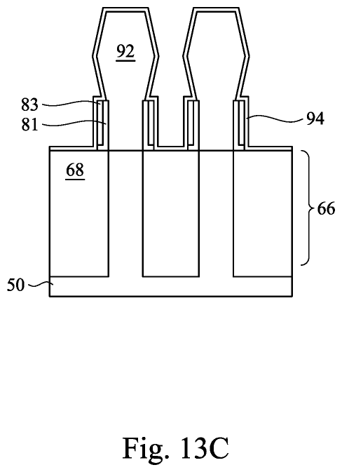

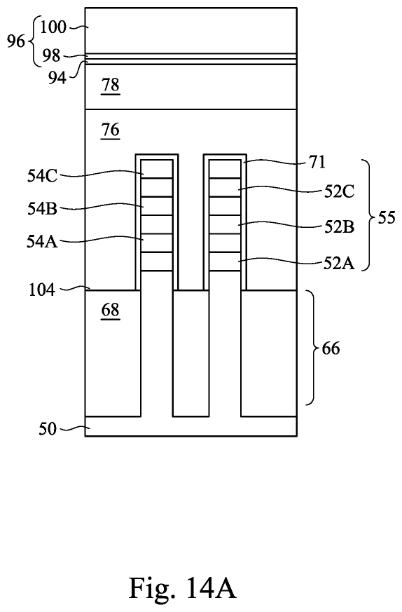

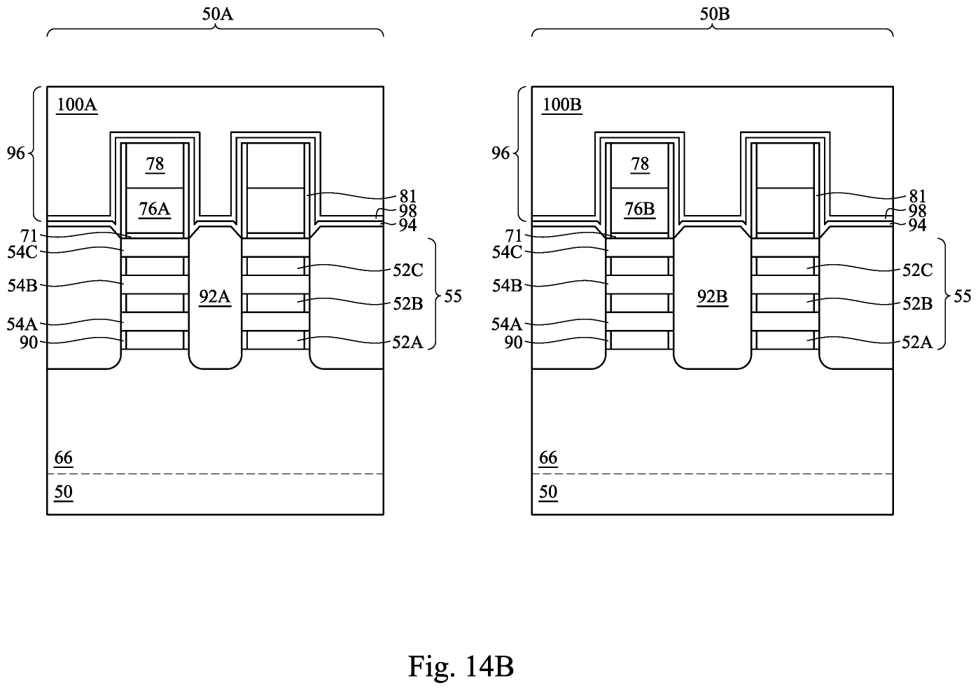

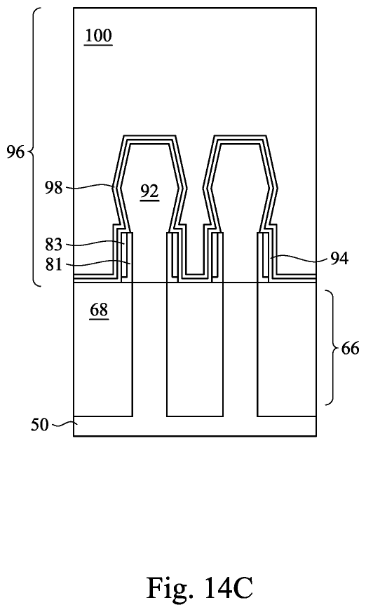

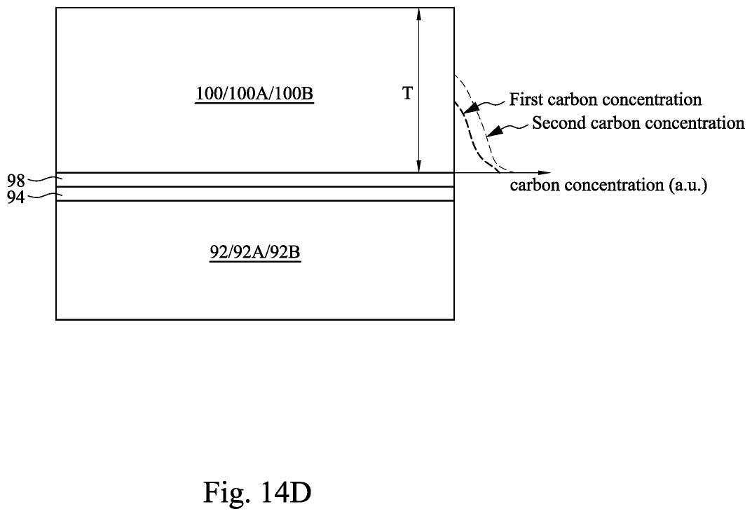

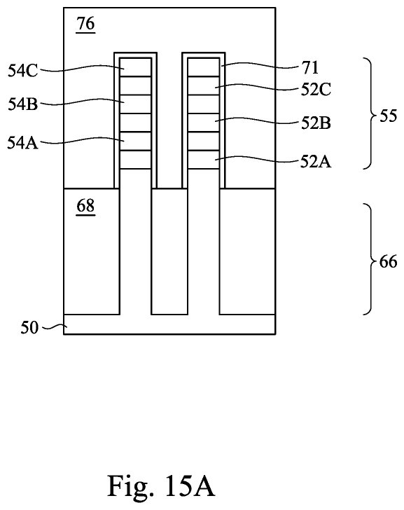

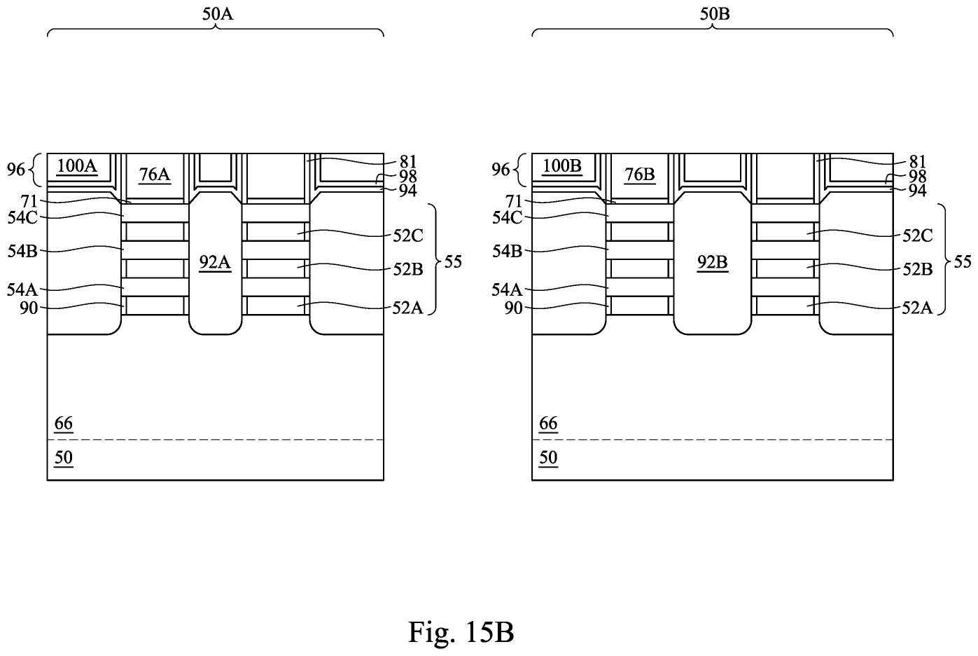

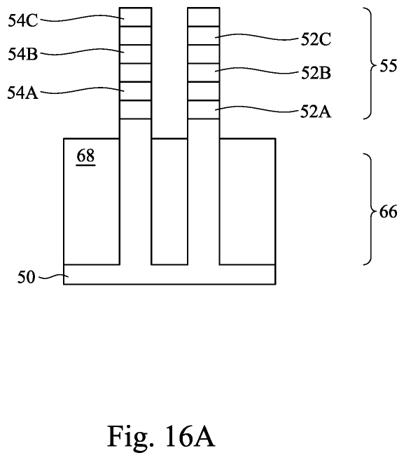

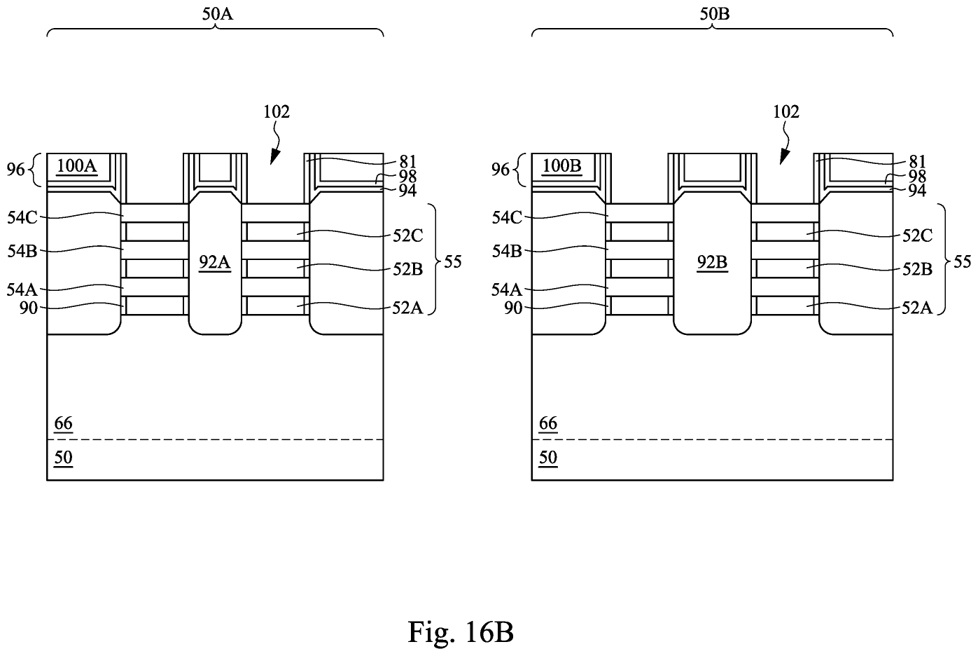

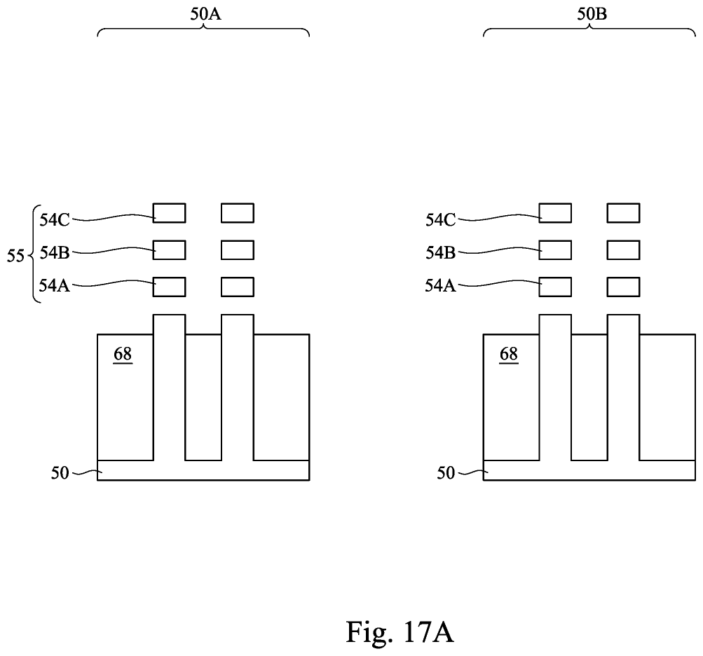

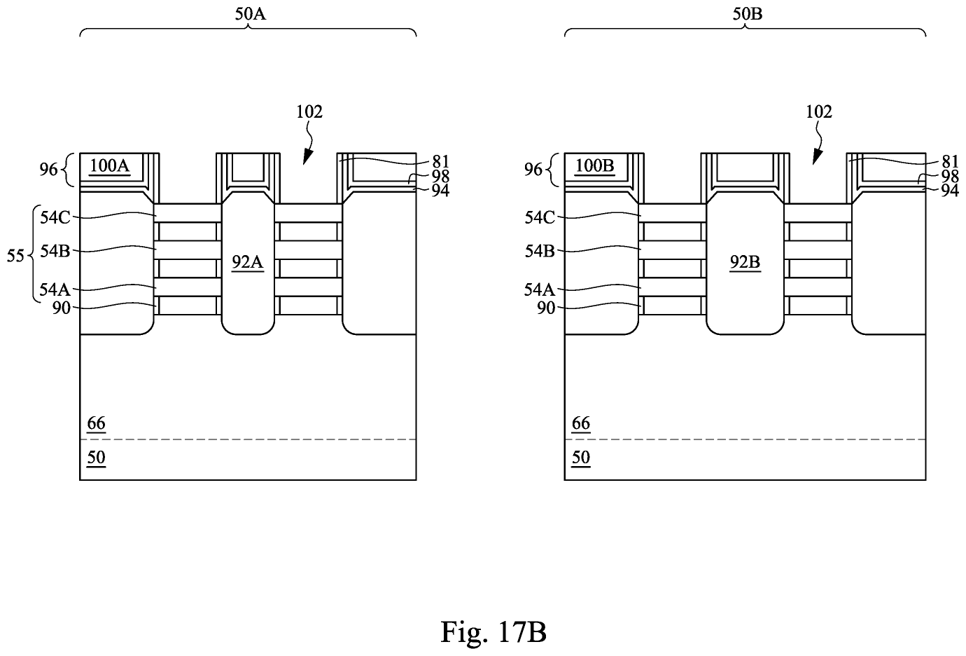

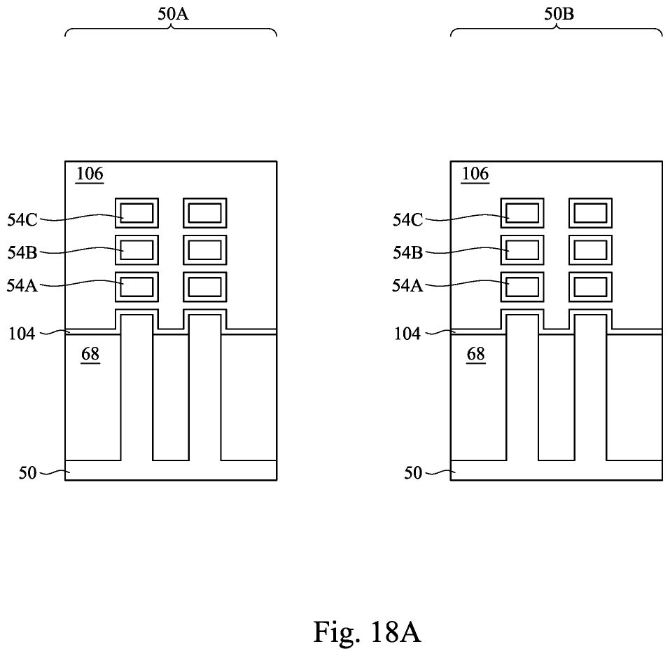

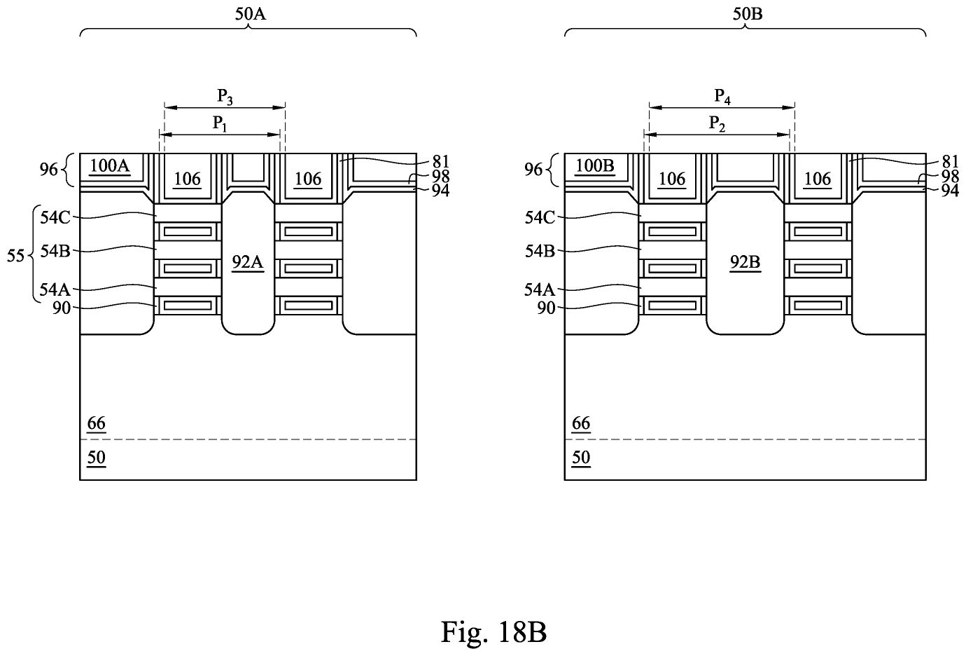

FIGS. 2 through 22C are cross-sectional views of intermediate stages in the manufacturing of nano-FETs, in accordance with some embodiments. FIGS. 2 through 5, 6A, 13A, 14A, 15A, 16A, 17A, 18A, 19A, 20A, 21A, and 22A illustrate reference cross-section A-A′ illustrated in FIG. 1. FIGS. 6B, 7B, 8B, 9B, 10B, 11B, 11C, 12B, 12D, 13B, 14B, 15B, 16B, 17B, 18B, 19B, 20B, 21B, and 22B illustrate reference cross-section B-B′ illustrated in FIG. 1. FIGS. 7A, 8A, 9A, 10A, 11A, 12A, 12C, 13C, 19C, 20C, 21C, and 22C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has a first region 50A and a second region 50B. The first region 50A may be a region for forming a plurality of transistors having a first density. The second region 50B may be a region for forming a plurality of transistors having a second density less than the first density. For example, the first region 50A may be a region for forming static random array memory (SRAM) devices or logic devices. The second region 50B may be a region for forming logic devices or input/output (I/O) devices. In some embodiments, the first region 50A and the second region 50B are regions for forming NMOS transistors, e.g., n-type nano-FETs. Alternatively, the first region 50A and the second region 50B are regions for forming PMOS transistors, e.g., p-type nano-FETs. The first region 50A may be physically separated from the second region 50B (as illustrated by divider 20), and any number of device features (e.g., other active devices, doped regions, isolation structures, etc.) may be disposed between the first region 50A and the second region 50B. Although one first region 50A and one second region 50B are illustrated, any number of first regions 50A and second regions 50B may be provided and can be arranged in any form.

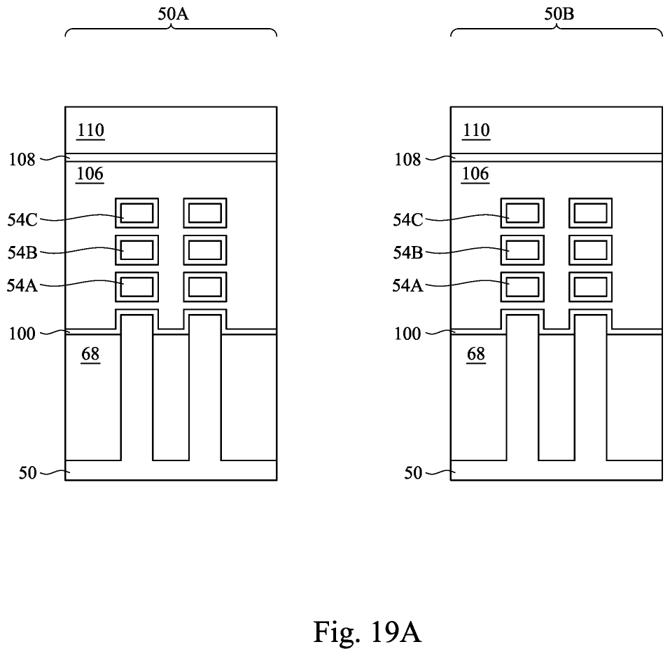

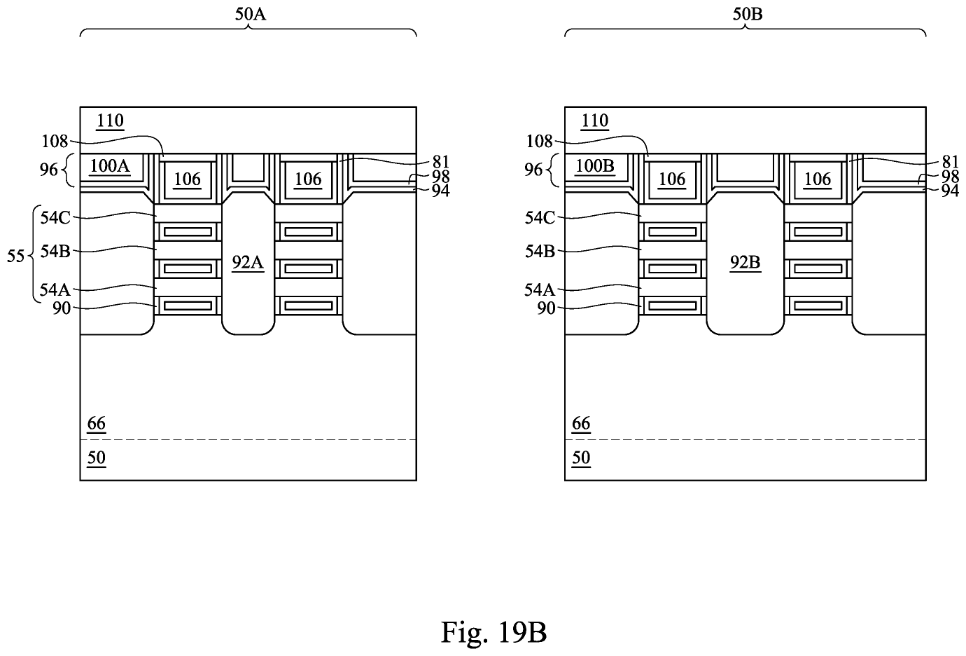

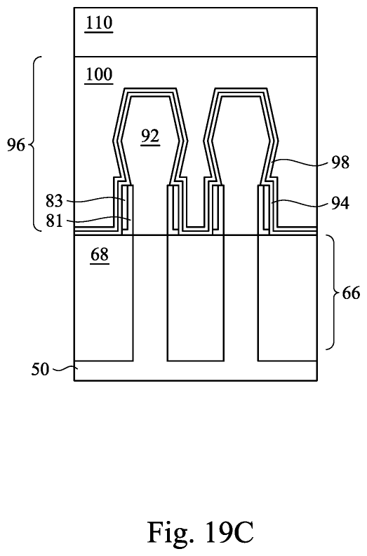

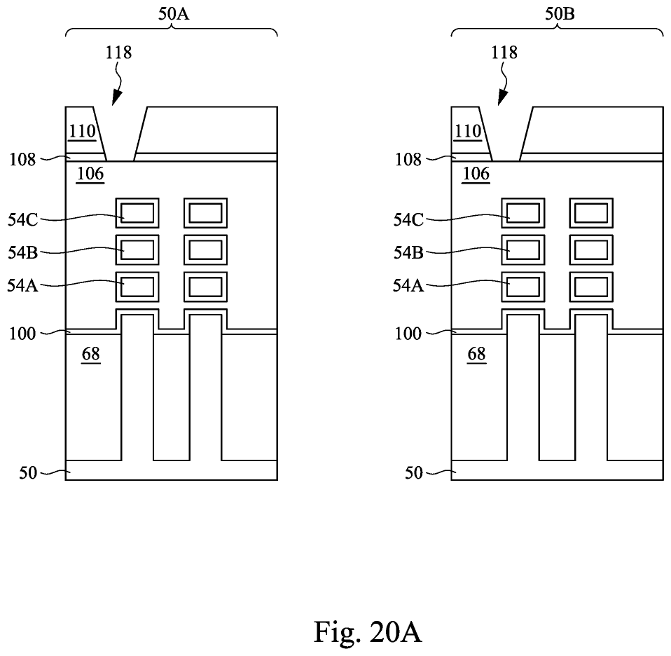

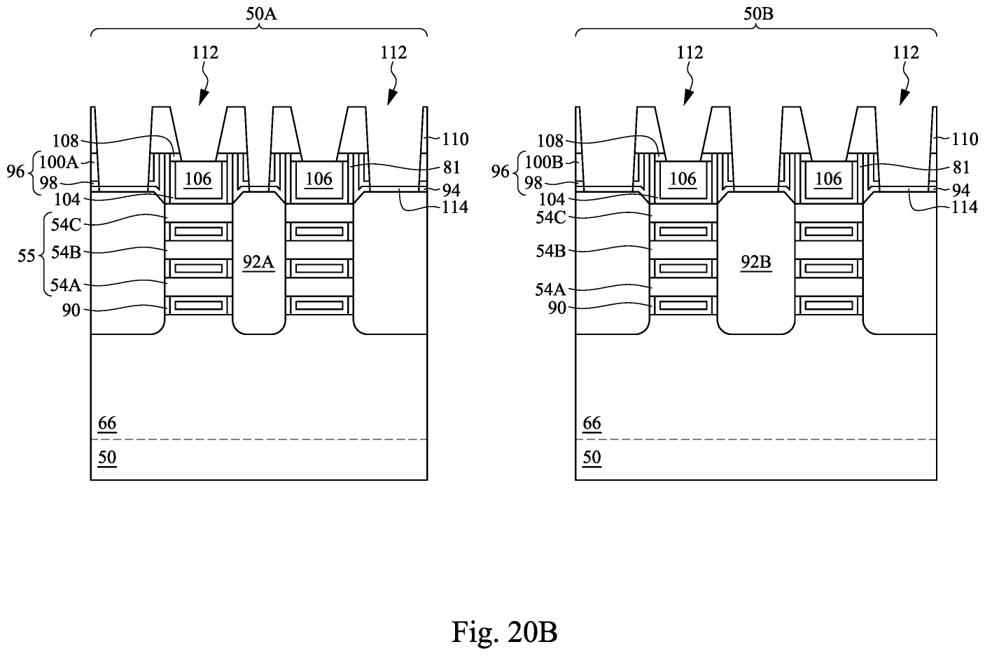

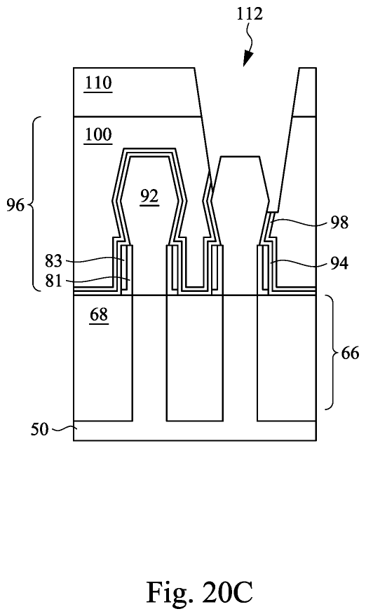

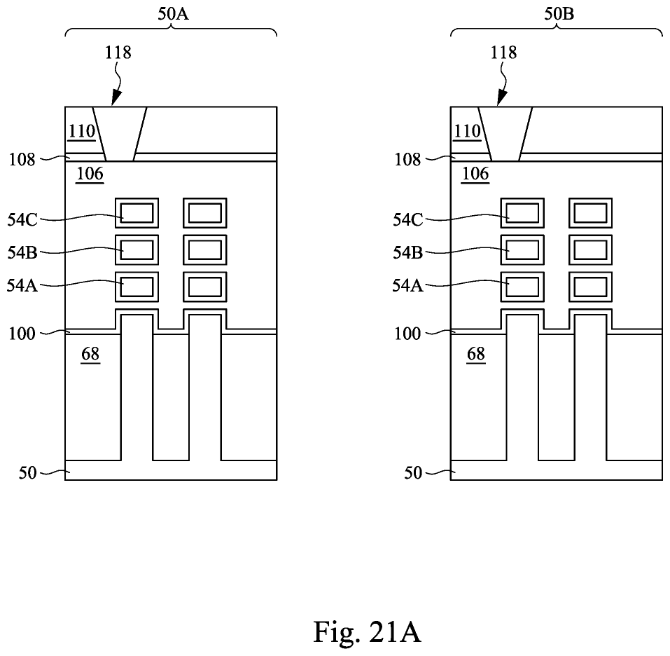

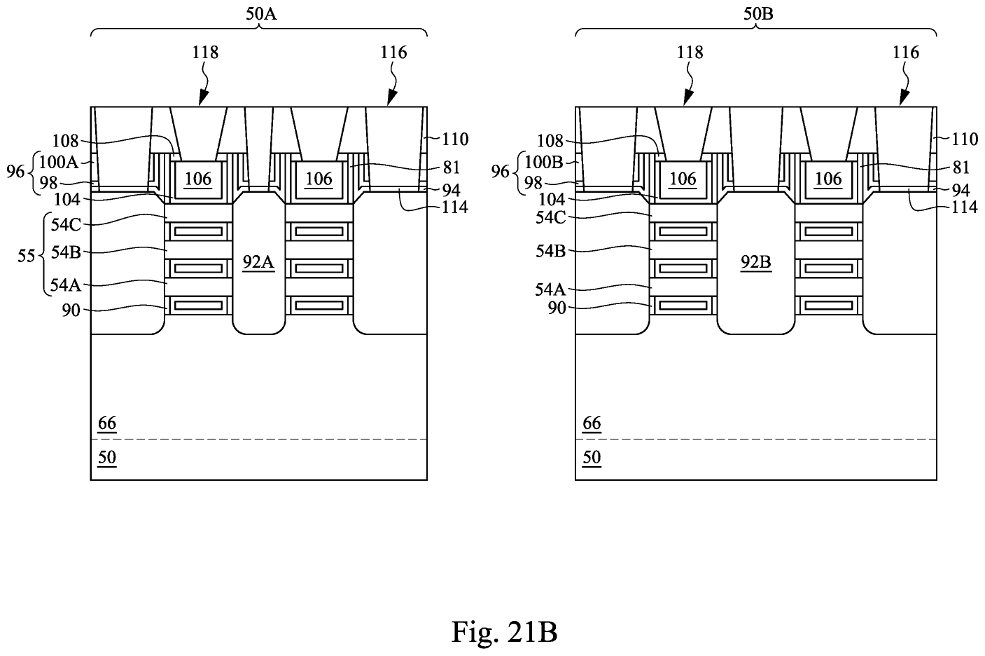

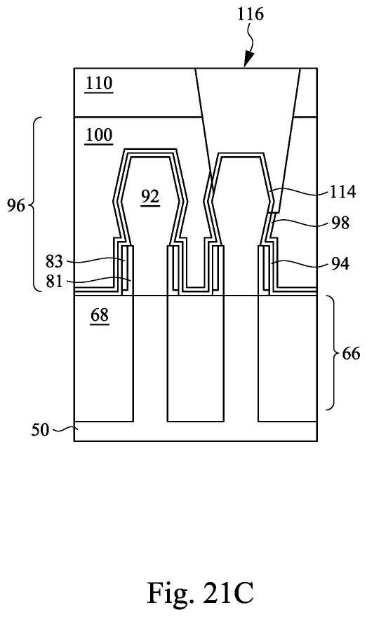

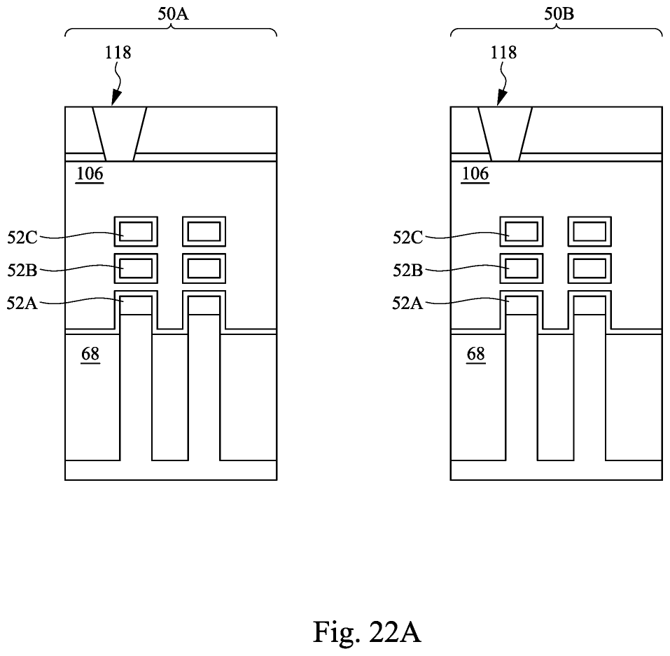

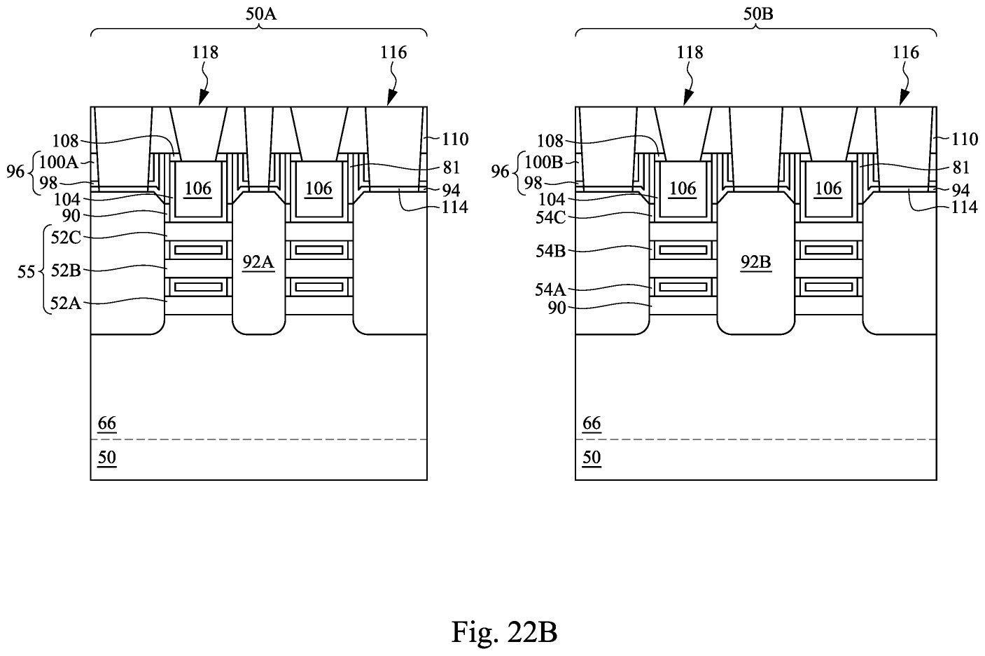

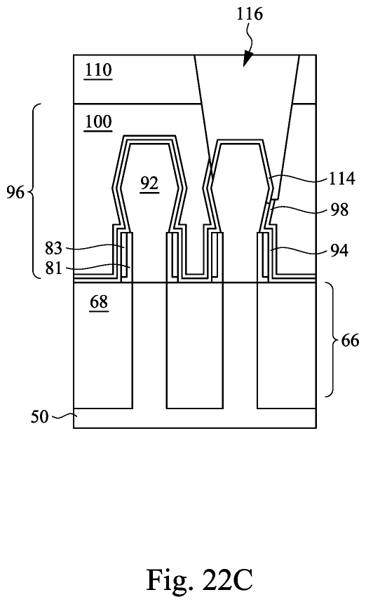

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 may be removed and the second semiconductor layers 53 may be patterned to form channel regions of nano-FETS in both the first region 50A and the second region 50B. In some embodiments, such as the embodiments illustrated in FIGS. 22A, 22B, and 22C, the second semiconductor layers 53 may be removed and the first semiconductor layers 51 may be patterned to form channel regions of nano-FETs in both the first region 50A and the second region 50B. In such embodiments described above, the channel regions in the first region 50A and the second region 50B may have a same material composition (e.g., silicon, silicon carbon, silicon germanium, or another semiconductor material) and be formed simultaneously.

In other embodiments (now shown in Figures), the second semiconductor layers 53 in the second region 50B may be removed and the first semiconductor layers 51 in the second region 50B may be patterned to form channel regions of nano-FETs in the second region 50B. Also, the first semiconductor layers 51 in the first region 50A may be removed and the second semiconductor layers 53 may be patterned to form channel regions of nano-FETs in the first region 50A. Nevertheless, in still other embodiments (not shown in Figures), the first semiconductor layers 51 in the second region 50B may be removed and the second semiconductor layers 53 in the second region 50B may be patterned to form channel regions of nano-FETs in the second region 50B, and the second semiconductor layers 53 in the first region 50A may be removed and the first semiconductor layers 51 in the first region 50A may be patterned to form channel regions of nano-FETs in the first region 50A.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

The first semiconductor materials and the second semiconductor materials may be materials having a high-etch selectivity to one another. As such, the first semiconductor layers 51 of the first semiconductor material may be removed without significantly removing the second semiconductor layers 53, thereby allowing the second semiconductor layers 53 to be patterned to form the channel regions of nano-FETs. Alternatively, the second semiconductor layers 53 of the second semiconductor material may be removed without significantly removing the first semiconductor layers 51 of the first semiconductor material, thereby allowing the first semiconductor layers 51 to be patterned to form the channel regions of nano-FETs. In various embodiments, the first semiconductor layers 51 or the second semiconductor layers 53 for forming the channel regions may be formed of a first semiconductor material suitable for p-type nano-FETs, such as silicon germanium, or the like. Alternatively, the first semiconductor layers 51 or the second semiconductor layers 53 forming the channel regions may be formed of a second semiconductor material suitable for n-type nano-FETs, such as silicon, silicon carbon, or the like.

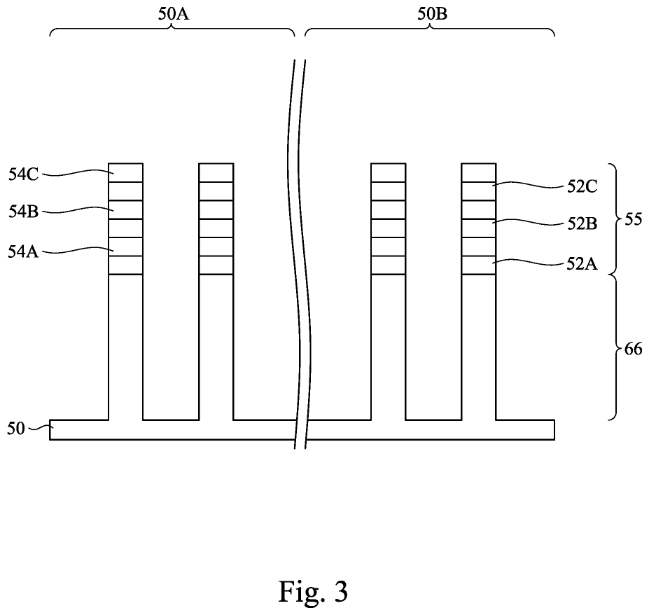

Referring now to FIG. 3, fins 66 are formed in the substrate 50 and nanostructures 55 are formed in the multi-layer stack 64, in accordance with some embodiments. The nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the first region 50A and the second region 50B as having substantially equal widths for illustrative purposes. In some embodiments, widths of the fins 66 in the first region 50A are greater or thinner than the fins 66 in the second region 50B. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

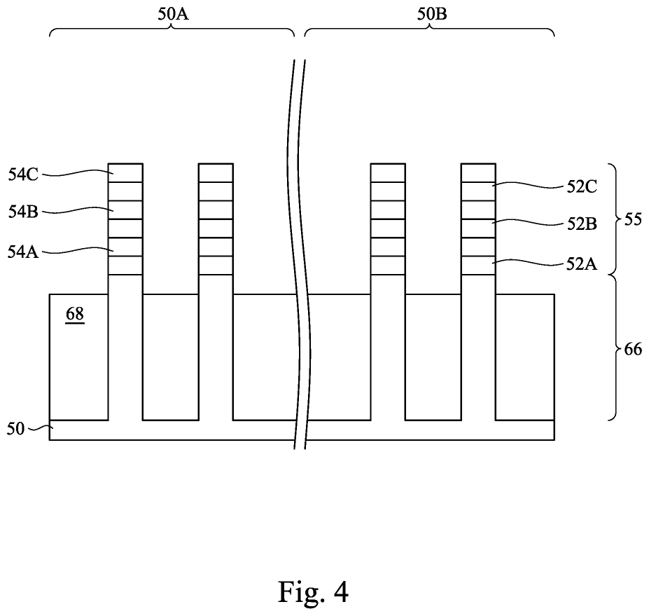

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the regions 50A and 50B protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting nanostructures 52) and the second semiconductor layers 53 (and resulting nanostructures 54) are illustrated and discussed herein as comprising the same materials in the second region 50B and the first region 50A for illustrative purposes only. As such, in some embodiments one or both of the first semiconductor layers 51 and the second semiconductor layers 53 may be different materials or formed in a different order in the second region 50B and the first region 50A.

Further in FIG. 4, appropriate wells (not separately illustrated) may be formed in the fins 66, the nanostructures 55, and/or the STI regions 68. For example, the wells in the first region 50A and the second region 50B may include p-type wells when the first region 50A and the second region 50B are regions for forming n-type nano-FETs. Alternatively, the wells in the first region 50A and the second region 50B may include n-type wells when the first region 50A and the second region 50B are regions for forming p-type nano-FETs. The p-type wells may be implanted with p-type impurities, such as boron, boron fluoride, indium, or the like, with a concentration in a range from about 10¹³ atoms/cm³ to about 10¹⁴ atoms/cm³. The n-type wells may be implanted with n-type impurities, such as phosphorus, arsenic, antimony, or the like, with a concentration in a range from about 10¹³ atoms/cm³ to about 10¹⁴ atoms/cm³.

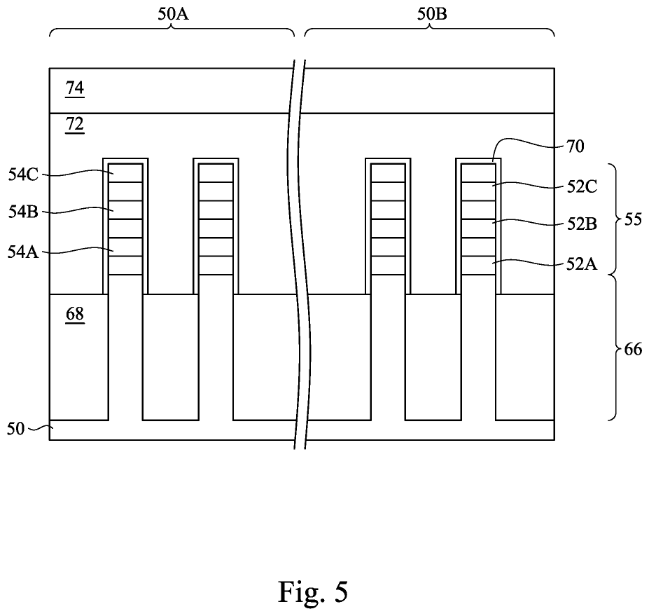

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the first region 50A and the second region 50B. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 21C illustrate various additional steps in the manufacturing of embodiment devices. FIGS. 6A, 7A, 8A, 9A, 10A, 11A, 12A, 12C, 13A, 13C, 14A, 14C, 14D, 15A, 16A, 19C, 20C, and 21C illustrate features in either the first region 50A or the second region 50B. In FIGS. 6A (along section A-A′ as illustrated in FIGS. 1) and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The dummy gates 76A and 76B may also have a lengthwise direction substantially perpendicular to the lengthwise direction of respective fins 66. The first dummy gates 76A and the second dummy gates 76B may be separated in the direction along the A-A′ section illustrated in FIG. 1, or they can be physically connected in this direction. Thus, the dummy gate 76 illustrated in FIG. 6A or in figures showing the same direction as FIG. 6A can be the first dummy gate 76A, the second dummy gate 76B, or a combination of the first dummy gate 76A and the second dummy gate 76B. As illustrated in FIG. 6B, two adjacent first dummy gates 76A in the first region 50A may have a first pitch P₁, and two adjacent second dummy gates 76B in the second region 50B may have a second pitch P₂ less than the first pitch P₁. In some embodiments, the first pitch P₁ is about 47 nm to about 53 nm. The second pitch P₂ is about 188 nm to about 195 nm. The first dummy gates 76A in the first region 50A may have substantially same lengths and/or widths as the second dummy gates 76B in the second region 50B.

In FIGS. 7A (along section C-C′ illustrated in FIGS. 1) and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. Appropriate type (e.g., p-type or n-type) impurities may be implanted into the exposed fins 66 and nanostructures 55 in the first region 50A and the second region 50B. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source/drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76A and 76B, and the dummy gate dielectrics 71, and the first spacers 81 are disposed on sidewalls of the masks 78, the dummy gates 76A and 76B, and dummy gate dielectrics 71. In other embodiments, a portion of the second spacer layer 82 may remain over the first spacer layer 80 adjacent the masks 78, the dummy gates 76A and 76B, and the dummy gate dielectrics 71.

It is noted that the above disclosure generally describes a process of forming spacers and LDD regions. Other processes and sequences may be used. For example, fewer or additional spacers may be utilized, different sequences of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

In FIGS. 9A and 9B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

In FIGS. 10A and 10B, portions of sidewalls of the layers of the multi-layer stack 64 formed of the first semiconductor materials (e.g., the first nanostructures 52) exposed by the first recesses 86 are etched to form sidewall recesses 88. Although sidewalls of the first nanostructures 52 in recesses 88 are illustrated as being straight in FIG. 10B, the sidewalls may be concave or convex. The sidewalls may be etched using isotropic etching processes, such as wet etching or the like. While etchants selective to the first semiconductor materials are used to etch the first nanostructures 52, the second nanostructures 54 and the substrate 50 remain relatively unetched as compared to the first nanostructures 52. Similarly, while etchants selective to the second semiconductor materials are used to etch the second nanostructures 54, the first nanostructures 52 and the substrate 50 remain relatively unetched as compared to the second nanostructures 54. In an embodiment in which the first nanostructures 52 or the second nanostructures 54 include, e.g., SiGe, a dry etch process with tetramethylammonium hydroxide (TMAH), ammonium hydroxide (NH₄OH), or the like may be used to etch sidewalls of the first nanostructures 52 or the second nanostructures 54. In an embodiment in which the first nanostructures 52 or the second nanostructures 54 include, e.g., Si or SiC, a wet or dry etch process with hydrogen fluoride, another fluorine-based etchant, or the like may be used to etch sidewalls of the first nanostructures 52 or the second nanostructures 54.

In FIGS. 11A-11C, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and a gate structure. As will be discussed in greater detail below, source/drain regions will be formed in the first recesses 86, while the first nanostructures 52 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54.

Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, and outer sidewalls of the first inner spacers 90 are concave. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A-12C) by subsequent etching processes, such as etching processes used to form gate structures.

In FIGS. 12A-12C, first epitaxial source/drain regions 92A and second epitaxial source/drain regions 92B (collectively referred to as epitaxial source/drain regions 92) are formed in the first recesses 86. In some embodiments, the epitaxial source/drain regions 92 may exert stress on the second nanostructures 54, thereby improving the performance of nano-FETs. As illustrated in FIG. 12B, the epitaxial source/drain regions 92 are formed in the first recesses 86 such that each dummy gate 76A or 76B is interposed between respective neighboring pairs of the epitaxial source/drain regions 92. In some embodiments, the first spacers 81 are used to separate the epitaxial source/drain regions 92 from the dummy gates 76A or 76B and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets. Alternatively, the epitaxial source/drain regions 92 may also include any acceptable material appropriate for p-type nano-FETs. For example, if the first nanostructures 52 are silicon germanium, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the first region 50A and the second region 50B, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12A. In other embodiments, adjacent epitaxial source/drain regions 92 remain separated after the epitaxy process is completed as illustrated by FIG. 12C. In the embodiments illustrated in FIGS. 12A and 12C, the first spacers 81 may be formed to a top surface of the STI regions 68, thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 68.

The epitaxial source/drain regions 92 may comprise one or more semiconductor material layers. For example, the epitaxial source/drain regions 92 may comprise a first semiconductor material layer 931, a second semiconductor material layer 932, and a third semiconductor material layer 933. Any number of semiconductor material layers may be used for the epitaxial source/drain regions 92. Each of the first semiconductor material layer 931, the second semiconductor material layer 932, and the third semiconductor material layer 933 may be formed of different semiconductor materials and may be doped to different dopant concentrations. In some embodiments, the first semiconductor material layer 931 may have a dopant concentration less than the second semiconductor material layer 932 and greater than the third semiconductor material layer 933. In embodiments in which the epitaxial source/drain regions 92 comprise three semiconductor material layers, the first semiconductor material layer 931 may be deposited, the second semiconductor material layer 932 may be deposited over the first semiconductor material layer 931, and the third semiconductor material layer 933 may be deposited over the second semiconductor material layer 932.

FIG. 12D illustrates an embodiment in which sidewalls of the first nanostructures 52 in the first region 50A and sidewalls of the second nanostructures 54 in the second region 50B are concave, outer sidewalls of the first inner spacers 90 are concave, and the first inner spacers 90 are recessed from sidewalls of the first nanostructures 52, respectively. As illustrated in FIG. 12D, the epitaxial source/drain regions 92 may be formed in contact with the first inner spacers 90 and may extend past sidewalls of the second nanostructures 54.

In FIGS. 13A-13C, a contact etch stop layer (CESL) 94 is conformally deposited in FIGS. 6A, 12B, and 12C (the processes of FIGS. 7A-12D do not alter the cross-section illustrated in FIGS. 6A), respectively. In some embodiments, the CESL 94 is disposed along surfaces of STI regions 68, the epitaxial source/drain regions 92, the masks 78, and the first spacers 81, in accordance with some embodiments. The CESL 94 may be a layer with a sufficient thickness able to prevent or reduce oxygen being diffused into the channel regions (e.g., nanostructures 54A-C). For example, the CESL 94 may block carbon or oxygen diffused from the first ILD 96 (see FIGS. 14A-C) during an anneal process. The CESL 94 may include a dielectric nitride layer, such as silicon nitride or the like. In some embodiments, the CESL 94 has a thickness of about 2 nm to about 5 nm.

In FIGS. 14A-14C, a first interlayer dielectric (ILD) 96 is formed over the CESL 94. The first ILD 96 includes a liner 98 and a main dielectric 100 over the liner 98. The liner 98 of the first ILD 96 is a thin layer conformally deposited over the CESL 94 prior to depositing the main dielectric 100. The liner 98 of the first ILD 96 may be a material including carbon, such as SiC, SiCN, SiOCN, SiOC, or the like. As will be discussed in more detail later, carbon in the liner 98 may diffuse into the main dielectric 100 and improve film quality of the main dielectric 100. In some embodiments, the liner 98 of the first ILD 96 also includes at least one element contained in the main dielectric 100 and at least one element contained in the CESL 94. In the illustrative embodiments, the liner 98 may be SiOCN, which includes oxygen contained in the main dielectric 100 and nitrogen contained in the CESL 94. Accordingly, the liner 98 of the first ILD 96 has similar characteristics with the main dielectric 100 and the CESL 94, thereby having good interfaces with the main dielectric 100 and the CESL 94, providing fewer dislocations and increased adhesions with the main dielectric 100 and CESL 94. In the embodiments in which the liner 98 is a SiOCN layer, the liner 98 may have a suitable thickness and hardness to facilitate subsequent planarization processing for exposing the dummy gates 76 (see FIG. 15B). For example, the liner 98 may have a thickness less than the thickness of the CESL 94, such as about 1 nm to about 3 nm. The hardness of liner 98 can be reduced by increasing the oxygen content in the liner 98.

The liner 98 may be deposited by a suitable method, such as CVD, ALD, or the like. In some embodiments, the ALD includes depositing a precursor containing silicon and a precursor containing nitrogen and carbon. The precursor containing silicon may include silanes, organosilanes, siloxanes, organosiloxanes, a combination thereof, or the like. The precursor containing nitrogen and carbon may include NH₂(CH₃), NH₂(C₂H₅), NH₂(C₃H₇), NH(CH₃)₂, NH(C₂H₅)₂, N(C₂H₅)₃, N(CH₃)₃, a combination thereof, or the like. The deposited precursors may then be oxidized by H₂O, O₂, or other suitable oxidizing agents.

The main dielectric 100 includes a first main dielectric 100A in the first region 50A and a second main dielectric 100B in the second region 50B, in accordance with some embodiments. The main dielectric 100 may include a silicon oxide material deposited by flowable CVD (FCVD) or the like, although other suitable materials can be used for the main dielectric 100. For example, a flowable dielectric may be deposited over the liner 98, including depositing in high aspect ratio trenches between adjacent first dummy gates 76A and between adjacent second dummy gates 76B. The flowable dielectric may be carbon-free silicon oxide. In an illustrative embodiment, a process for forming the flowable dielectric may include reacting a silicon-containing precursor and an oxygen-containing precursor to form a flowable silicon oxide film at a low temperature (e.g., lower than about 100 degrees Celsius). Suitable silicon-containing precursor for forming the flowable dielectric may include carbon-free silicon silanes, including aminosilane such as trisilylamine, silatrane, a combination thereof, or the like, or halogenated silane such as tetrachlorosilane, tetrabromosiliane, a combination thereof, or the like. Suitable oxygen-containing precursor for forming the flowable dielectric may include O₂, O₃, NO, NO₂, N₂O, H₂O, H₂O₂, a combination thereof, or the like.

An anneal process may be then performed to cure the flowable dielectric and form the main dielectric 100 once the flowable dielectric is deposited and flows into the high-aspect ratio trenches. The anneal process may include at least two stages. For example, the first stage of the anneal process may introduce H₂O steam or other oxygen-containing gas for oxidizing residual Si dangling bonds, and may replace Si—N—Si bonds to Si—O—Si bonds when the main dielectric 100 is formed from a precursor such as aminosilane. The second stage of the anneal may include introducing N₂ or other nitrogen-containing gas for converting Si—OH bonds to Si—O—Si bonds of the main dielectric 100 by a dry annealing. The first and second stages of the anneal process may be performed at a temperature between about 400 degrees Celsius and about 500 degrees Celsius. Experiments have found that when the annealing temperature of the anneal process is lower than about 500 degrees Celsius, it can effectively reduce deactivation of the activated dopants in the epitaxial source/drain regions 92. Such dopant deactivation may harm the electrical performance of the nano-FETs.

During the anneal process, carbon in the liner 98 is diffused into the main dielectric 100. Effective carbon diffusion from the liner 98 to the main dielectric 100 may occur when the annealing temperature is above about 400 degrees Celsius. Carbon diffused into the main dielectric 100 may improve the film quality of the main dielectric 100, such as improving the resistance of the main dielectric 100 against cleaning agents or etchants in subsequent processes (e.g., gate replacement processes described in FIGS. 15A-18B). As such, in some embodiments in which the main dielectric 100 has degraded film quality due to insufficient curing under the low-temperature anneal process (e.g., less than about 500 degrees Celsius), carbon diffused into the main dielectric 100 can improve the film quality of the main dielectric 100, thereby solving the problem of degraded film quality induced by the low-temperature anneal process.

In some embodiments, the first carbon concentration of the first main dielectric 100A gradually decreases from the bottom of the first main dielectric 100A toward the top of the first main dielectric 100A, and the second carbon concentration of the second main dielectric 100B gradually decreases from the bottom of the second main dielectric 100B toward the top of the second main dielectric 100B. For example, the peak carbon concentration in the first main dielectric 100A or the peak carbon concentration in the second main dielectric 100B is at a depth near the liner 98 or at the bottom of the first main dielectric 100A or the second main dielectric 100B.

In some embodiments in which the liner 98 is a SiOCN layer, after the anneal process, the atomic ratio of carbon to silicon of the liner 98 may drop from between about 1 and about 12 to between about 0.1 and about 0.2, while the atomic ratio of oxygen to silicon of the liner 98 may remain at between about 2 and about 2.6, and the atomic ratio of nitrogen to silicon of the liner may remain at between about 0.23 and about 0.36. In some embodiments, the main dielectric 100, either in the first region 50A or in the second region 50B, the average atomic ratio of carbon to silicon is less than about 0.1. The main dielectric 100 may also include nitrogen that may come from the nitrogen-containing gas in the anneal process, or residues of precursors, such as with an average atomic ratio of nitrogen to silicon less than about 0.1. In some embodiments, the atomic ratio of oxygen to silicon in the main dielectric 100 is about 1.85 to about 2.1. In some embodiments, the liner 98 has a nitrogen concentration greater than that of the main dielectric 100. In some embodiments, the liner 98 has an oxygen concentration greater than that of the main dielectric 100.

In some embodiments, the anneal process provides a same thermal budget to the first region 50A and the second region 50B, but it was found that the film quality may be degraded more in the first main dielectric 100A in the first region 50A than the second main dielectric 100B in the second region 50B, which may be caused by the high transistor density in the first region 50A. This film degradation problem may be more serious for the nano-FETs in the first region 50A than the nano-FETs in the second region 50B. Since the pitch adjacent gate contacts (see FIG. 18A) in the first region 50A is small, small damages or loss of the first main dielectric 100A may cause leakage or short between the adjacent gate contacts in the first region 50A. With carbon diffusing into the first main dielectric 100A from the liner 98, film quality of the first main dielectric 100A can be improved, and the film degradation problem can be alleviated or solved.

In some embodiments, the anneal process provides different thermal budgets to the first region 50A and the second region 50B. For example, the anneal process provides a lower thermal budget to the first region 50A than the second region 50B. The first epitaxial source/drain regions 92A may be more thermal sensitive than the second epitaxial source/drain regions 92B, such as being easier to suffer dopant deactivation than the second epitaxial source/drain regions 92B, because the volume of the first epitaxial source/drain regions 92A between dummy gates 76A having the tight pitch P₁ may be smaller than the volume of the second epitaxial source/drain regions 92B. Providing different thermal budgets to the first region 50A and the second region 50B may be achieved using a wafer support that can provide localized heat conduction. The wafer support may include a first zone to provide a first temperature to the first region 50A and a second zone to provide a second temperature to the second region 50B. Only providing a low thermal budget to the first region 50A may cause the first main dielectric 100A to have a film degradation problem in some embodiments, and this problem may be severe for the nano-FETs in the first region 50A since the pitch adjacent gate contacts (see FIG. 18A) in the first region 50A is small. With carbon diffusing into the first main dielectric 100A from the liner 98, the film quality of the first main dielectric 100A can be improved, and the film degradation problem can be alleviated or solved.

FIG. 14D illustrates a comparison of the first carbon concentration of the first main dielectric 100A and the second carbon concentration of the second main dielectric 100B along the thickness T of the main dielectric 100 when different thermal budgets are given to the first region 50A and the second region 50B, in accordance with some embodiments. As illustrated in FIG. 14D, more carbon can travel a longer distance in the second main dielectric 100B than in the first main dielectric 100A, since a higher thermal budget is provided to the liner 98 and the second main dielectric 100B in the second region 50B. In such embodiments, the second carbon concentration of the second main dielectric 100B at a depth level with the top of the second dummy gates 76B (or at a depth level with the top of gate electrodes 106 in a resulting structure illustrated in FIG. 18B) may be greater than the first carbon concentration of the first main dielectric 100A at a depth level with the top of the first dummy gates 76A (or at a depth level with the top of gate electrodes 106 in a resulting structure illustrated in FIG. 18B).

Carbon diffused into the main dielectric 100 may improve the film quality of the main dielectric 100 that is only annealed at a low temperature (e.g., lower than about 500 degrees Celsius), especially for the first main dielectric 100A. In some embodiments, by adding the liner 98 before forming the main dielectric 100, the etching rate of the first main dielectric 100A with respect to dilute hydrofluoric acid is improved to 4.8 times faster than the etching rate of etching a thermal oxide from 6.5 times faster than that. In some embodiments, by adding the liner 98 before forming the main dielectric 100, the etching rate of the second main dielectric 100B with respect to dilute hydrofluoric acid is improved to 4.2 times faster than the etching rate of etching a thermal oxide from 5 times faster than that.

In FIGS. 15A-15C, a planarization process, such as a CMP, may be performed to level the top surface of the first ILD 96 with the top surfaces of the dummy gates 76, in accordance with some embodiments. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

In FIGS. 16A and 16B, the dummy gates 76, and the mask layer 74 (if present), are removed in one or more etching steps so that second recesses 102 are formed. Portions of the dummy gate dielectrics 71 in the second recesses 102 are also removed. In some embodiments, the dummy gates 76 and dummy gate dielectrics 71 are removed by an anisotropic dry etch process. For example, the etching process may include a dry etch process using reaction gas(es) that selectively etch the dummy gates 76 at a faster rate than the main dielectric 100 of the first ILD 96 or the first spacers 81. Because the film quality of the main dielectric 100 has been improved, the main dielectric 100 can have sufficient resistance against the etching process. Each second recess 102 exposes and/or overlies portions of nanostructures 55, which act as channel regions in subsequently completed nano-FETs. Portions of the nanostructures 55, which act as the channel regions, are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

In FIGS. 17A and 17B, the first nanostructures 52 in the first region 50A and in the second region 50B are removed, extending the second recesses 102. The first nanostructures 52 may be removed by an isotropic etching process such as wet etching or the like using etchants which are selective to the materials of the first nanostructures 52, while the second nanostructures 54, the substrate 50, the first ILD 96, the STI regions 68 remain relatively unetched as compared to the first nanostructures 52. In embodiments in which the first nanostructures 52 include, e.g., SiGe, tetramethylammonium hydroxide (TMAH), ammonium hydroxide (NH₄OH), or the like may be used to remove the first nanostructures 52. In embodiments in which the first nanostructures 52 include silicon, hydrogen fluoride, another fluorine-based etchant, or the like may be used to remove the first nanostructures 52.

In FIGS. 18A and 18B, gate dielectric layers 104 and gate electrodes 106 are formed for replacement gates. The gate dielectric layers 104 are deposited conformally in the second recesses 102. The gate dielectric layers 104 may be formed on top surfaces and sidewalls of the substrate 50 and on top surfaces, sidewalls, and bottom surfaces of the second nanostructures 54. The gate dielectric layers 104 may also be deposited on top surfaces of the first ILD 96, the CESL 94, the first spacers 81, and the STI regions 68.

In accordance with some embodiments, the gate dielectric layers 104 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 104 include a high-k dielectric material, and in these embodiments, the gate dielectric layers 104 may have a k value greater than about 7.0 and may include a metal oxide or a silicate of hafnium, aluminum, zirconium, lanthanum, manganese, barium, titanium, lead, and combinations thereof. The structure of the gate dielectric layers 104 may be the same or different in the first region 50A and the second region 50B. The formation methods of the gate dielectric layers 104 may include molecular-beam deposition (MBD), ALD, PECVD, and the like.

The gate electrodes 106 are deposited over the gate dielectric layers 104, respectively, and fill the remaining portions of the second recesses 102. The gate electrodes 106 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 106 are illustrated in FIGS. 18A and 18B, the gate electrodes 106 may comprise any number of liner layers, any number of work function tuning layers, and a fill material. Any combination of the layers which make up the gate electrodes 106 may be deposited between adjacent ones of the second nanostructures 54.

The formation of the gate dielectric layers 104 in the first region 50A and the second region 50B may occur simultaneously such that the gate dielectric layers 104 in each region are formed from the same materials, and the formation of the gate electrodes 106 may occur simultaneously such that the gate electrodes 106 in each region are formed from the same materials. In some embodiments, the gate dielectric layers 104 in each region may be formed by distinct processes, such that the gate dielectric layers 104 may be different materials and/or have a different number of layers, and/or the gate electrodes 106 in each region may be formed by distinct processes, such that the gate electrodes 106 may be different materials and/or have a different number of layers. Various masking steps may be used to mask and expose appropriate regions when using distinct processes.

After the filling of the second recesses 102, a planarization process, such as a CMP, may be performed to remove the excess portions of the gate dielectric layers 104 and the material of the gate electrodes 106, which excess portions are over the top surface of the first ILD 96. The remaining portions of material of the gate electrodes 106 and the gate dielectric layers 104 thus form replacement gate structures of the resulting nano-FETs. The gate electrodes 106 and the gate dielectric layers 104 may be collectively referred to as “gate structures.” In some embodiments, one or more cleaning processes are performed on the gate electrodes 106 and the first ILD 96 after the planarization process. Because the film quality of the main dielectric 100 has been improved, the main dielectric 100 can have sufficient resistance against the cleaning agents in the cleaning process. In some embodiments, adjacent gate structures in the first region 50A have the first pitch P₁, and adjacent gate electrodes 106 in the first region 50A have a third pitch P₃ substantially equal to the first pitch P₁. In some embodiments, adjacent gate structures in the second region 50B have the second pitch P₂, and adjacent gate electrodes 106 in the second region 50B have a fourth pitch P₄ substantially equal to the second pitch P₂.

In FIGS. 19A-19C, the gate structure (including the gate dielectric layers 104 and the corresponding overlying gate electrodes 106) is recessed, so that a recess is formed directly over the gate structure and between opposing portions of first spacers 81. A gate mask 108 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as contacts 118, discussed below with respect to FIGS. 21A and 21B) penetrate through the gate mask 108 to contact the top surface of the recessed gate electrodes 106.

As further illustrated by FIGS. 19A-19C, a second ILD 110 is deposited over the first ILD 96 and over the gate mask 108. In some embodiments, the second ILD 110 is a flowable dielectric formed by FCVD. In some embodiments, the second ILD 110 is formed of a dielectric material such as PSG, BSG, BPSG, USG, or the like, and may be deposited by any suitable method, such as CVD, PECVD, or the like.

In FIGS. 20A-20C, the second ILD 110, the first ILD 96, the CESL 94, and the gate masks 108 are etched to form third recesses 112 exposing surfaces of the epitaxial source/drain regions 92 and/or the gate structure. The third recesses 112 may be formed by etching using an anisotropic etching process, such as RIE, NBE, or the like. In some embodiments, the third recesses 112 may be etched through the second ILD 110 and the first ILD 96 using a first etching process; may be etched through the gate masks 108 using a second etching process; and may then be etched through the CESL 94 using a third etching process. A mask, such as a photoresist, may be formed and patterned over the second ILD 110 to mask portions of the second ILD 110 from the first etching process and the second etching process. In some embodiments, the etching process may over-etch, and therefore, the third recesses 112 extend into the epitaxial source/drain regions 92 and/or the gate structure, and a bottom of the third recesses 112 may be level with (e.g., a same level, or having a same distance from the substrate), or lower than (e.g., closer to the substrate) the epitaxial source/drain regions 92 and/or the gate structure. Although FIGS. 20B illustrate the third recesses 112 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 112 are formed, silicide regions 114 are formed over the epitaxial source/drain regions 92. In some embodiments, the silicide regions 114 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 114. The un-reacted portions of the deposited metal are then removed, e.g., by an etching process. Although silicide regions 114 are referred to as silicide regions, silicide regions 114 may also be germanide regions, or silicon germanide regions (e.g., regions comprising silicide and germanide). In an embodiment, the silicide region 114 comprises TiSi, and has a thickness in a range between about 2 nm and about 10 nm.

Next, in FIGS. 21A-C, contacts 118 and 116 (may also be referred to as contact plugs) are formed in the third recesses 112. The contacts 118 and 116 may each comprise one or more layers, such as barrier layers, diffusion layers, and fill materials. For example, in some embodiments, the contacts 118 and 116 each include a barrier layer and a conductive material, and is electrically coupled to the underlying conductive feature (e.g., gate electrode 106 and/or silicide region 114 in the illustrated embodiment). The contacts 118 are electrically coupled to the gate electrodes 106 and may be referred to as gate contacts, and the contacts 116 are electrically coupled to the silicide regions 114 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 110. Because the film quality of the first ILD 96 has been improved and can be sustained after various cleaning and etching processes, leakage or short between adjacent gate contacts 118 may be reduced or prevented.

FIGS. 22A-C illustrate cross-sectional views of a device according to some alternative embodiments. FIGS. 22A illustrates reference cross-section A-A′ illustrated in FIG. 1. FIG. 22B illustrates reference cross-section B-B′ illustrated in FIG. 1. FIG. 22C illustrates reference cross-section C-C′ illustrated in FIG. 1. In FIGS. 22A-C, like reference numerals indicate like elements formed by like processes as the structure of FIGS. 21A-C. However, in FIGS. 22A-C, channel regions in the first region 50A and the second region 50B comprise the first nanostructures 52, and the bottommost of the first nanostructures 52 are in contact with the fins 66. The structure of FIGS. 22A-C may be formed, for example, by removing the second nanostructures 54 from the first region 50A and the second region 50B simultaneously; depositing the gate dielectric layers 104 and the gate electrodes 106 around the first nanostructures 52.

As discussed above, embodiments of the present disclosure provide an ILD with good film quality against various cleaning and etching processes, even though the interlayer dielectric is only cured by a low-temperature anneal process to reduce or avoid dopant deactivation in the source/drain regions. In some embodiments, such ILD can be formed by simply forming a carbon-containing liner before forming the main dielectric of the ILD. The ILD and processes of fabricating it can benefit transistors with a high density, such as SRAM devices or logic devices.

In an embodiment, a method of a semiconductor device fabrication is provided. The method includes forming a dummy gate interposed between source/drain regions; forming an etch stop layer over the dummy gate and the source/drain regions, wherein the etch stop layer comprises a nitride layer; forming an interlayer dielectric over the etch stop layer, wherein the interlayer dielectric comprises a liner and a main dielectric over the liner, wherein the liner comprises carbon, wherein forming the main dielectric comprises: forming a flowable dielectric around the dummy gate and over the source/drain regions; and curing the flowable dielectric, wherein carbon in the liner is diffused into the flowable dielectric while curing the flowable dielectric; removing the etch stop layer, the liner, and the main dielectric over the dummy gate by a planarization process to expose the dummy gate; and replacing the dummy gate with a gate. In an embodiment, curing the flowable dielectric comprises performing an anneal process at a temperature between 400 degrees Celsius and 500 degrees Celsius. In an embodiment, the anneal process comprises a first stage and a second stage, wherein the interlayer dielectric is exposed to an oxygen-containing gas at the first stage and exposed to a nitrogen-containing gas at the second stage. In an embodiment, the main dielectric comprises a carbon concentration gradually decreasing from a lower portion of the main dielectric to an upper portion of the main dielectric. In an embodiment, the liner is a SiOCN layer. In an embodiment, the etch stop layer has a first thickness, and the liner has a second thickness, wherein the first thickness is greater than the second thickness. In an embodiment, the atomic ratio of carbon to silicon of the liner drops to between 0.1 and 0.2 from between 1 and 12 after curing the flowable dielectric.

A method of a semiconductor device fabrication is provided. The method includes forming a first channel, a second channel, a third channel, and a fourth channel over a substrate; forming a first dummy gate, a second dummy gate, a third dummy gate, and a fourth dummy gate over the first channel, the second channel, the third channel, and the fourth channel, respectively, wherein a first pitch between the first dummy gate and the second dummy gate is less than a second pitch between the third dummy gate and the fourth dummy gate; forming an etch stop layer over the substrate, the first dummy gate, the second dummy gate, the third dummy gate, and the fourth dummy gate; forming an interlayer dielectric over the etch stop layer, wherein the interlayer dielectric includes a liner over the etch stop layer and a main dielectric over the liner, wherein the liner includes carbon, wherein forming the main dielectric includes forming a flowable dielectric over the liner, between the first dummy gate and the second dummy gate, and between the third dummy gate and the fourth dummy gate; and providing a first thermal budget to a first portion of flowable dielectric between the first dummy gate and the second dummy gate and a second thermal budget to a second portion of the flowable dielectric between the third dummy gate and the fourth dummy gate to cure the first portion and the second portion of the flowable dielectric, wherein the first thermal budget is less than the second thermal budget, wherein while providing the first thermal budget and the second thermal budget, carbon in the liner is diffused into the first portion of and the second portion of the flowable dielectric; removing the etch stop layer, the liner, and the main dielectric over the first dummy gate, the second dummy gate, the third dummy gate, and the fourth dummy gate by a planarization process to expose the first dummy gate, the second dummy gate, the third dummy gate, and the fourth dummy gate; and replacing the first dummy gate, the second dummy gate, the third dummy gate, and the fourth dummy gate with a first gate, a second gate, a third gate, and a fourth gate, respectively. In an embodiment, a carbon concentration of the first portion of the main dielectric gradually decreases from a first depth of the first portion of the first main dielectric to a second depth of the second portion of the first main dielectric, wherein the first depth is lower than the second depth. In an embodiment, a first carbon concentration of the first portion of the main dielectric at a first depth level with the top of the first dummy gate is greater than a second carbon concentration of the second portion of the main dielectric at a second depth level with the top of the third dummy gate. In an embodiment, the first thermal budget and the second thermal budget are provided by an anneal process with a temperature not greater than 500 degrees Celsius. In an embodiment, the liner and the etch stop layer both include nitrogen, and the liner and the main dielectric both include oxygen. In an embodiment, the flowable dielectric is carbon free before curing the flowable dielectric, and the liner is a SiOCN layer. In an embodiment, the etch stop layer has a first thickness, and the liner has a second thickness, wherein the first thickness is greater than the second thickness.

In an embodiment, a semiconductor device includes a channel over substrate; a gate over the channel and interposed between source/drain regions; an etch stop layer around sidewalls of the gate and over the substrate and source/drain regions; and an interlayer dielectric over the etch stop layer, wherein the interlayer dielectric includes a liner and a main dielectric over the liner, wherein the liner and the main dielectric both include at least silicon, oxygen, and carbon, wherein the main dielectric includes a lower portion and an upper portion, wherein a first carbon concentration of the main dielectric at the lower portion is greater than a second carbon concentration of the main dielectric at the upper portion. In an embodiment, the carbon concentration in the main dielectric gradually decreases from the second concentration to the first concentration along a thickness direction of the main dielectric. In an embodiment, the liner is a SiOCN layer. In an embodiment, the main dielectric and the liner both further include nitrogen. In an embodiment, the nitrogen concentration of the liner is greater than the nitrogen concentration of the main dielectric. In an embodiment, the etch stop layer has a first thickness, and the liner has a second thickness, wherein the first thickness is greater than the second thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of a semiconductor device fabrication, the method comprising:
forming a dummy gate interposed between source/drain regions;
forming an etch stop layer over the dummy gate and the source/drain regions, wherein the etch stop layer comprises a nitride layer;
forming an interlayer dielectric over the etch stop layer, wherein the interlayer dielectric comprises a liner and a main dielectric over the liner, wherein the liner comprises carbon, wherein forming the main dielectric comprises:
forming a flowable dielectric around the dummy gate and over the source/drain regions; and
curing the flowable dielectric, wherein carbon in the liner is diffused into the flowable dielectric while curing the flowable dielectric;
removing the etch stop layer, the liner, and the main dielectric over the dummy gate by a planarization process to expose the dummy gate; and
replacing the dummy gate with a gate.

2. The method of claim 1, wherein curing the flowable dielectric comprises performing an anneal process at a temperature between 400 degrees Celsius and 500 degrees Celsius.

3. The method of claim 2, wherein the anneal process comprises a first stage and a second stage, wherein the interlayer dielectric is exposed to an oxygen-containing gas at the first stage and exposed to a nitrogen-containing gas at the second stage.

4. The method of claim 1, wherein the main dielectric comprises a carbon concentration gradually decreasing from a lower portion of the main dielectric to an upper portion of the main dielectric.

5. The method of claim 1, wherein the liner is a SiOCN layer.

6. The method of claim 1, wherein the etch stop layer has a first thickness, and the liner has a second thickness, wherein the first thickness is greater than the second thickness.

7. The method of claim 1, wherein the atomic ratio of carbon to silicon of the liner drops to between 0.1 and 0.2 from between 1 and 12 after curing the flowable dielectric.

8. A method of a semiconductor device fabrication, the method comprising:
forming a first channel, a second channel, a third channel, and a fourth channel over a substrate;
forming a first dummy gate, a second dummy gate, a third dummy gate, and a fourth dummy gate over the first channel, the second channel, the third channel, and the fourth channel, respectively, wherein a first pitch between the first dummy gate and the second dummy gate is less than a second pitch between the third dummy gate and the fourth dummy gate;
forming an etch stop layer over the substrate, the first dummy gate, the second dummy gate, the third dummy gate, and the fourth dummy gate;
forming an interlayer dielectric over the etch stop layer, wherein the interlayer dielectric comprises a liner over the etch stop layer and a main dielectric over the liner, wherein the liner comprises carbon, wherein forming the main dielectric comprises:
forming a flowable dielectric over the liner, between the first dummy gate and the second dummy gate, and between the third dummy gate and the fourth dummy gate; and
providing a first thermal budget to a first portion of flowable dielectric between the first dummy gate and the second dummy gate and a second thermal budget to a second portion of the flowable dielectric between the third dummy gate and the fourth dummy gate to cure the first portion and the second portion of the flowable dielectric, wherein the first thermal budget is less than the second thermal budget, wherein while providing the first thermal budget and the second thermal budget, carbon in the liner is diffused into the first portion of and the second portion of the flowable dielectric;
removing the etch stop layer, the liner, and the main dielectric over the first dummy gate, the second dummy gate, the third dummy gate, and the fourth dummy gate by a planarization process to expose the first dummy gate, the second dummy gate, the third dummy gate, and the fourth dummy gate; and
replacing the first dummy gate, the second dummy gate, the third dummy gate, and the fourth dummy gate with a first gate, a second gate, a third gate, and a fourth gate, respectively.

9. The method of claim 8, wherein a carbon concentration of the first portion of the main dielectric gradually decreases from a first depth of the first portion of the first main dielectric to a second depth of the second portion of the first main dielectric, wherein the first depth is lower than the second depth.

10. The method of claim 8, wherein a first carbon concentration of the first portion of the main dielectric at a first depth level with the top of the first dummy gate is greater than a second carbon concentration of the second portion of the main dielectric at a second depth level with the top of the third dummy gate.

11. The method of claim 8, wherein the first thermal budget and the second thermal budget are provided by an anneal process with a temperature not greater than 500 degrees Celsius.

12. The method of claim 8, wherein the liner and the etch stop layer both comprise nitrogen, and the liner and the main dielectric both comprise oxygen.

13. The method of claim 8, wherein the flowable dielectric is carbon free before curing the flowable dielectric, and the liner is a SiOCN layer.

14. The method of claim 8, wherein the etch stop layer has a first thickness, and the liner has a second thickness, wherein the first thickness is greater than the second thickness.

15. A semiconductor device, comprising:
a channel over a substrate;
a gate over the channel and interposed between source/drain regions;
an etch stop layer around sidewalls of the gate and over the substrate and source/drain regions; and
an interlayer dielectric over the etch stop layer, wherein the interlayer dielectric comprises a liner and a main dielectric over the liner, wherein the liner and the main dielectric both comprise at least silicon, oxygen, and carbon, wherein the main dielectric comprises a lower portion and an upper portion, wherein a first carbon concentration of the main dielectric at the lower portion is greater than a second carbon concentration of the main dielectric at the upper portion.

16. The semiconductor device of claim 15, the carbon concentration in the main dielectric gradually decreases from the second carbon concentration to the first carbon concentration along a thickness direction of the main dielectric.

17. The semiconductor device of claim 15, wherein the liner is a SiOCN layer.

18. The semiconductor device of claim 15, wherein the main dielectric and the liner both further comprise nitrogen.

19. The semiconductor device of claim 18, wherein the nitrogen concentration of the liner is greater than the nitrogen concentration of the main dielectric.

20. The semiconductor device of claim 15, wherein the etch stop layer has a first thickness, and the liner has a second thickness, wherein the first thickness is greater than the second thickness.
